(19) United States
(12) Patent Application Publication
(10) Pub. No.: US 2019/0057959 A1
(43) Pub. Date: Feb. 21, 2019

(54) SEMICONDUCTOR DEVICE AND STRUCTURE WITH THERMAL ISOLATION

(71) Applicant: Monolithic 3D Inc., San Jose, CA (US)

(72) Inventors: Zvi Or-Bach, San Jose, CA (US); Jin-Woo Han, San Jose, CA (US); Brian Cronquist, San Jose, CA (US)

(73) Assignee: Monolithic 3D Inc., San Jose, CA (US)

(21) Appl. No.: 16/166,112

(22) Filed: Oct. 21, 2018

Related U.S. Application Data
(63) Continuation-in-part of application No. 15/173,686, filed on Jun. 5, 2016.
(60) Provisional application No. 62/239,931, filed on Oct. 11, 2015.
(60) Provisional application No. 62/236,951, filed on Oct. 4, 2015.
(60) Provisional application No. 62/198,126, filed on Jul. 29, 2015.
(60) Provisional application No. 62/174,507, filed on Jun. 11, 2015.
(60) Provisional application No. 62/172,079, filed on Jun. 6, 2015.

(51) Int. Cl. H01L 25/18; H01L 21/762; H01L 23/48; H01L 21/768; H01L 23/528

(52) U.S. Cl. CPC H01L 25/18; H01L 21/76256; H01L 21/76254; H01L 24/32; H01L 23/481; H01L 21/76898; H01L 23/528; H01L 21/76259

(57) ABSTRACT

A semiconductor device, the device including: a first level of logic circuits, the logic circuits include a plurality of first transistors interconnected by a plurality of metal layers; a thermal isolation layer overlaying the first level; a second level of memory circuits, the memory circuits include an array of memory cells, where the second level is overlaying the thermal isolation layer; and connections from the logic circuits to the memory array including vias, where the vias have a diameter of less than 400 nm, and where a majority of the thermal isolation layer includes a material with a less than 0.5 W/m·K thermal conductivity.

This application is a continuation in part of pending U.S. patent application Ser. No. 15/173,686, filed on Jun. 5, 2016, and claims benefit of provisional U.S. Patent Application No. 62/239,931, filed on Oct. 11, 2015; provisional U.S. Patent Application No. 62/236,951, filed on Oct. 4, 2015; provisional U.S. Patent Application No. 62/198,126, filed on Jul. 29, 2015; provisional U.S. Patent Application No. 62/174,507, filed on Jun. 11, 2015; and provisional U.S. Patent Application No. 62/172,079, filed on Jun. 6, 2015. This application claims priority to the foregoing applications. The contents of the foregoing applications are incorporated herein by reference.

### BACKGROUND OF THE INVENTION

### 1. Field of the Invention

This application relates to the general field of Integrated Circuit (IC) devices and fabrication methods, and more particularly to multilayer or Three Dimensional Integrated Circuit (3D-IC) devices and fabrication methods.

### 2. Discussion of Background Art

Silicon has been the preferred substrate for electronic devices. But for some applications other materials and/or crystals would be preferred, especially for electro-optic applications.

There are many techniques to construct 3D stacked integrated circuits or chips including:
Through-silicon via (TSV) technology: Multiple layers of transistors (with or without wiring levels) can be constructed separately. Following this, they can be bonded to each other and connected to each other with through-silicon vias (TSVs).
Monolithic 3D technology: With this approach, multiple layers of transistors and wires can be monolithically constructed. Some monolithic 3D and 3DIC approaches are described in U.S. Pat. Nos. 8,273,610, 8,298,875, 8,362,482, 8,378,715, 8,379,458, 8,450,804, 8,557,632, 8,574,929, 8,581,349, 8,642,416, 8,669,778, 8,674,470, 8,687,399, 8,742,476, 8,803,206, 8,836,073, 8,902,663, 8,994,404, 9,023,688, 9,029,173, 9,030,858, 9,117,749, 9,142,553, 9,219,005, 9,385,058, 9,509,313, 9,640,531, 9,691,760, 9,711,407, 9,721,927, 9,871,034, 9,953,870, 9,953,994, 10,014,292, 10,014, 318; and pending U.S. Patent Application Publications and application Ser. Nos. 15/173,686, 62/562,457, 62/645,794, 62/651,722; 62/681,249, 62/713,345; and PCT Applications: PCT/US2010/052093, PCT/US2011/042071, PCT/US2016/52726, PCT/US2017/052359, PCT/US2018/016759. The entire contents of the foregoing patents, publications, and applications are incorporated herein by reference.

Electro-Optics: There is also work done for integrated monolithic 3D including layers of different crystals, such as U.S. Pat. Nos. 8,283,215, 8,163,581, 8,753,913, 8,823,122, 9,197,804, 9,419,031 and 9,941,319. The entire contents of the foregoing patents, publications, and applications are incorporated herein by reference.

Additionally the 3D technology according to some embodiments of the invention may enable some very innovative IC devices alternatives with reduced development costs, novel and simpler process flows, increased yield, and other illustrative benefits.

### SUMMARY

The invention may be directed to multilayer or Three Dimensional Integrated Circuit (3D IC) devices and fabrication methods. An early work on monolithic 3D was presented in U.S. Pat. No. 7,052,941 and follow-on work in related patents includes U.S. Pat. No. 7,470,598. A technique which has been used over the last 20 years to build SOI wafers, called “Smart-Cut” or “Ion-Cut”, was presented in U.S. Pat. No. 7,470,598 as one of the options to perform layer transfer for the formation of a monolithic 3D device. Ion-Cut layer transfer was presented in U.S. Pat. No. 9,197,804 for the construction of 3D image sensor and micro-display. In this application at least the modified ELTRAN process presented in U.S. patent application Ser. Nos. 14/607,077 and 14/642,724 is used as an alternative method for layer transfer. All of the forgoing patents and patent applications in this paragraph are incorporated herein by reference.

In one aspect, a semiconductor device, the device comprising: a first level of logic circuits, said logic circuits comprise a plurality of first transistors interconnected by a plurality of metal layers; a thermal isolation layer overlaying said first level; a second level of memory circuits, said memory circuits comprise an array of memory cells, wherein said second level is overlaying said thermal isolation layer; and connections from said logic circuits to said memory array comprising vias, wherein said vias have a diameter of less than 400 nm, and wherein a majority of said thermal isolation layer comprises a material with a less than 0.5 W/m·K thermal conductivity.

In another aspect, a semiconductor device, the device comprising: a first level of logic circuits, said logic circuits comprise a plurality of first transistors interconnected by a plurality of metal layers; a thermal isolation layer overlaying said first level; a second level of memory circuits, said memory circuits comprise an array of memory cells, wherein said second level is overlaying said thermal isolation layer; and connections from said logic circuits to said memory array comprising vias, wherein said vias have a diameter of less than 400 nm, and wherein said thermal isolation layer has a thickness of more than 400 nm and less than 4 microns.

In another aspect, a semiconductor device, the device comprising: a first level of logic circuits, said logic circuits comprise a plurality of first transistors interconnected by a plurality of metal layers; a thermal isolation layer overlaying said first level; a second level of memory circuits, said memory circuits comprise an array of memory cells, wherein said second level is overlaying said thermal isolation layer; and connections from said logic circuits to said memory array comprising vias, wherein said vias have a diameter of less than 400 nm, and wherein said device has an unpackaged size less than 0.5 mm for its horizontal or vertical sides.

### BRIEF DESCRIPTION OF THE DRAWINGS

Various embodiments of the invention will be understood and appreciated more fully from the following detailed description, taken in conjunction with the drawings in which:

FIGS. 1A-1I are exemplary illustrations of a porous silicon based donor wafer with a multi-layered porous structure processed to form Stratum-3 devices and transferred to a carrier substrate;

FIGS. 2A-2C are exemplary illustrations of a porous silicon based Stratum-2 transfer structure formation;

FIGS. 3A-3D are exemplary illustrations of a dual strata donor structure formation;

FIGS. 4A-4C are exemplary illustrations of a dual strata donor structure and formation integrated with a target base wafer and interconnects;

FIGS. 5A-5D are exemplary illustrations of fabrication of back side illumination image sensor utilizing a porous cut layer/region;

FIGS. 6A-6B are exemplary illustrations of 3D IC image sensors and formation thereof; and

FIGS. 7A-7E, 7E-1, 7F-7I are exemplary illustrations of 3D image sensors with pixel electronics and bifacial illumination (Directed absorption and Reflected absorption) and formation thereof;

FIGS. 8A-8C are exemplary illustrations of a data centric processor sub-system that may be called a Processed Data Device—“PDD”;

FIG. 9 is an exemplary illustrations of a prior art vertical nanowire transistors structure;

FIGS. 10A-10G are exemplary illustrations of fabrication of simple access to both sides of a VNWT (Vertical NanoWire Transistor);

FIG. 11A is an exemplary illustration of elements/symbols which will be utilized in the following drawings, at least FIGS. 11B to 11E, to illustrate some cell library exemplary constructions for VNWT type logic;

FIGS. 11B-11E are exemplary illustrations of a macro-cell library for VNWT type logic;

FIGS. 12A-12G are exemplary illustrations of an alternative dual strata donor structure and formation integrated with a target base wafer and interconnects;

FIG. 13 is an exemplary illustration of a processing structure with a P-well guard ring insulator that may form a device with a guard ring insulator structure;

FIGS. 14A and 14B are exemplary illustrations of a substrate with protection areas or transistor designated regions;

FIGS. 15A and 15B are exemplary illustrations of another substrate with protected areas or transistor designated regions; and

FIGS. 16A-16F are exemplary illustrations of the formation and structure of multi monocrystalline region dual porous layer/region substrate.

### DETAILED DESCRIPTION

An embodiment of the invention is now described with reference to the drawing figures. Persons of ordinary skill in the art will appreciate that the description and figures illustrate rather than limit the invention and that in general the figures are not drawn to scale for clarity of presentation. Such skilled persons will also realize that many more embodiments are possible by applying the inventive principles contained herein and that such embodiments fall within the scope of the invention which is not to be limited except by any appended claims.

Some drawing figures may describe process flows for building devices. The process flows, which may be a sequence of steps for building a device, may have many structures, numerals and labels that may be common between two or more adjacent steps. In such cases, some labels, numerals and structures used for a certain step's figure may have been described in the previous steps' figures.

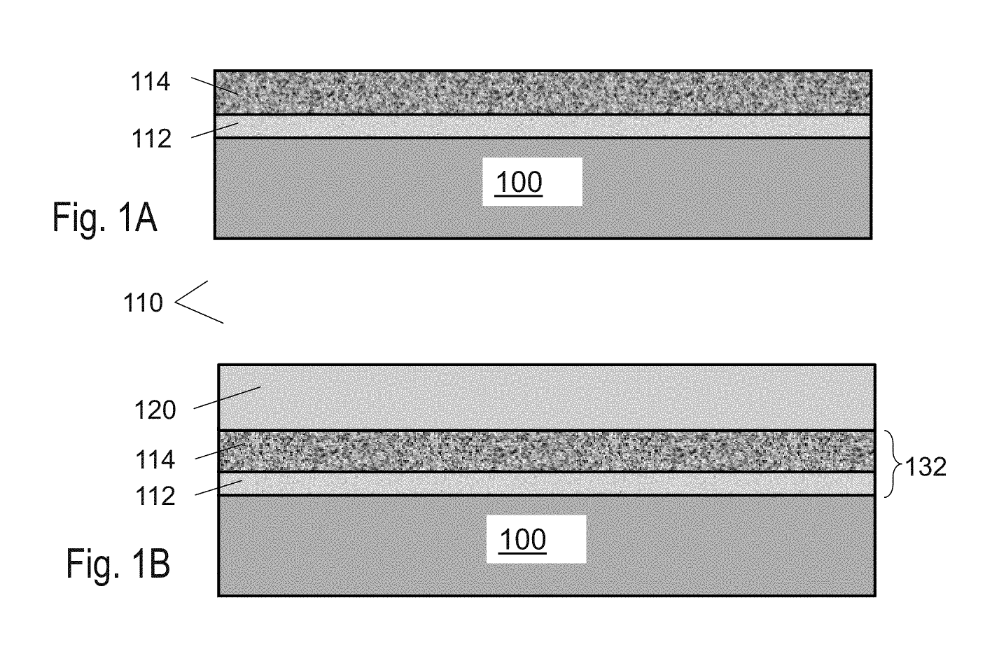

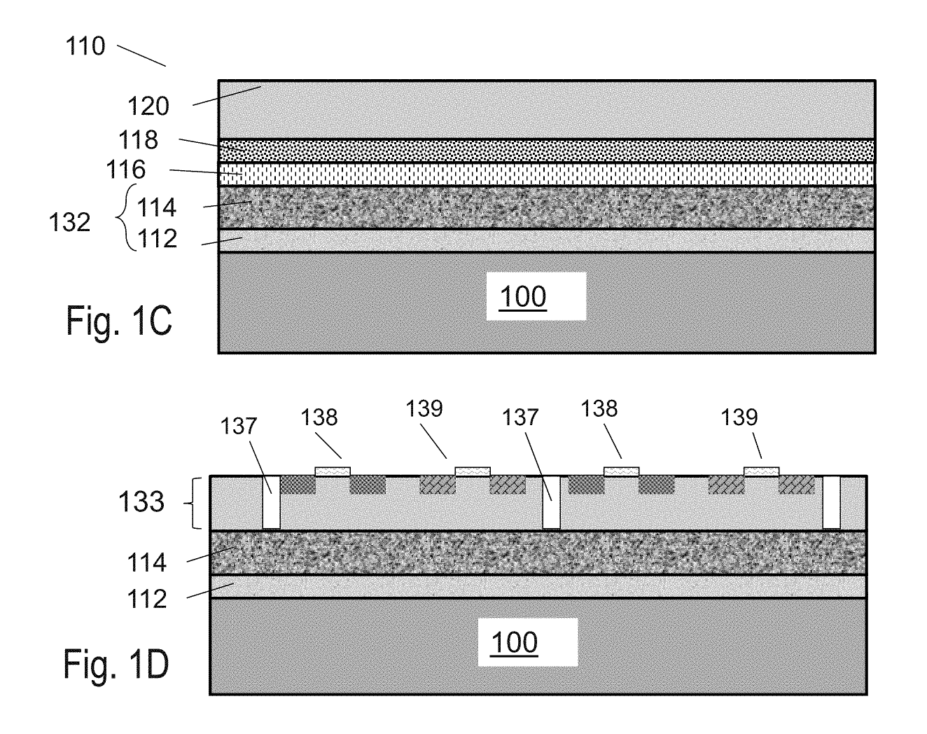

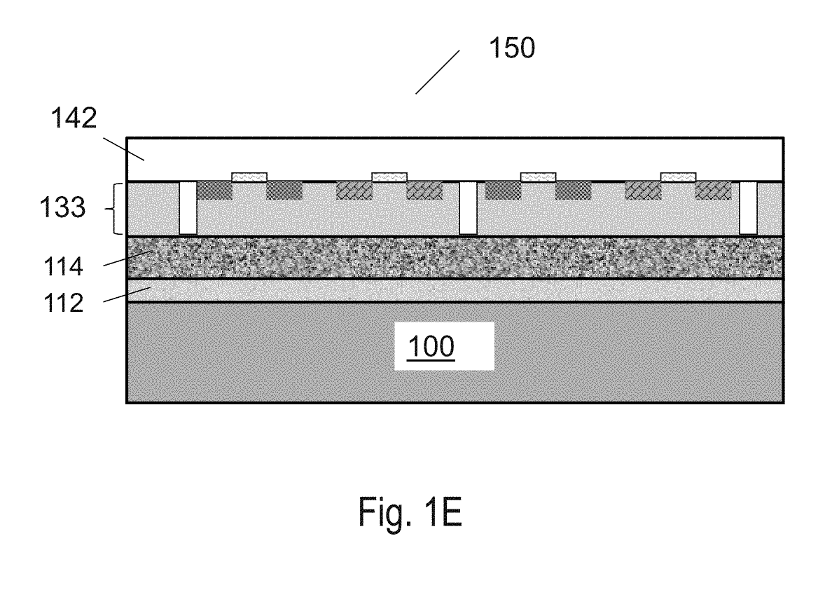

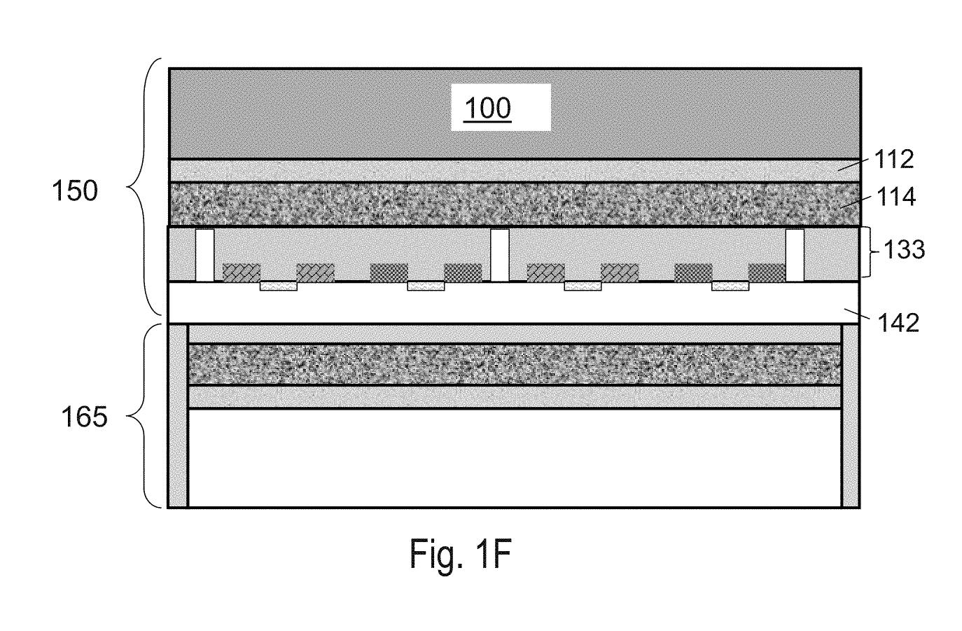

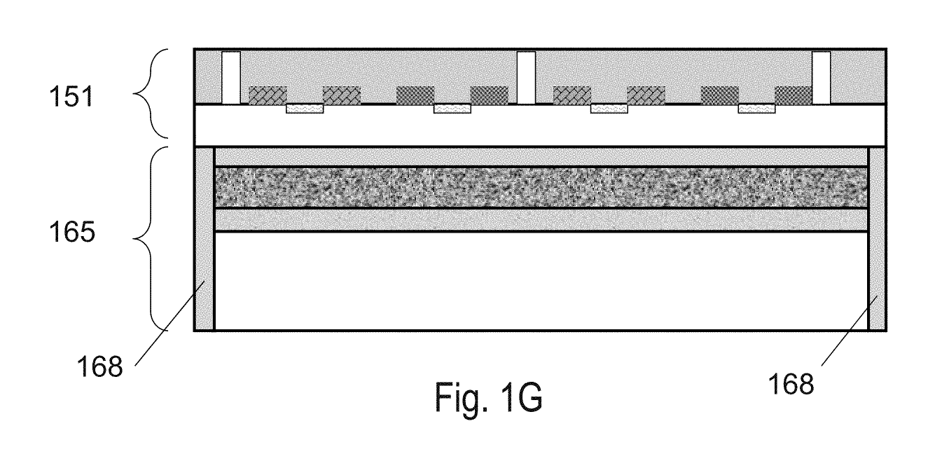

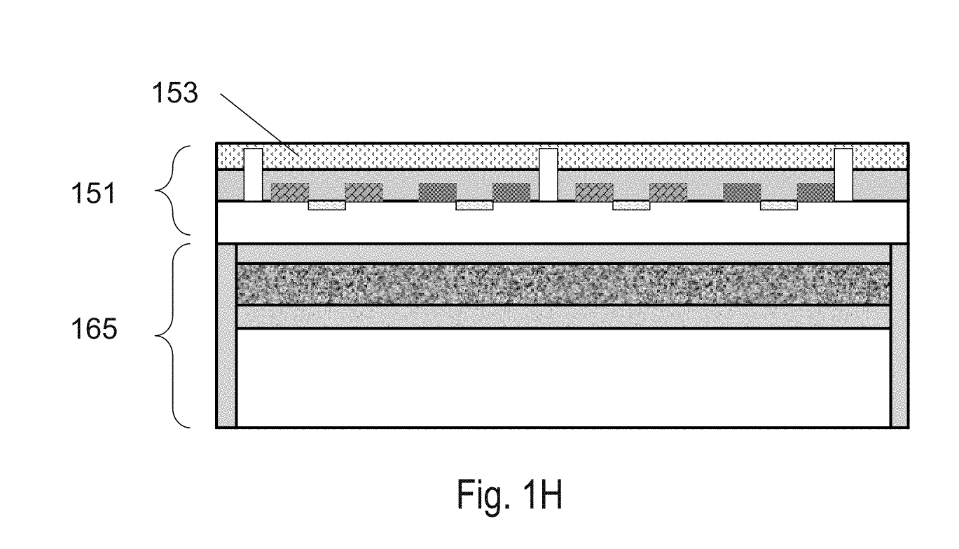

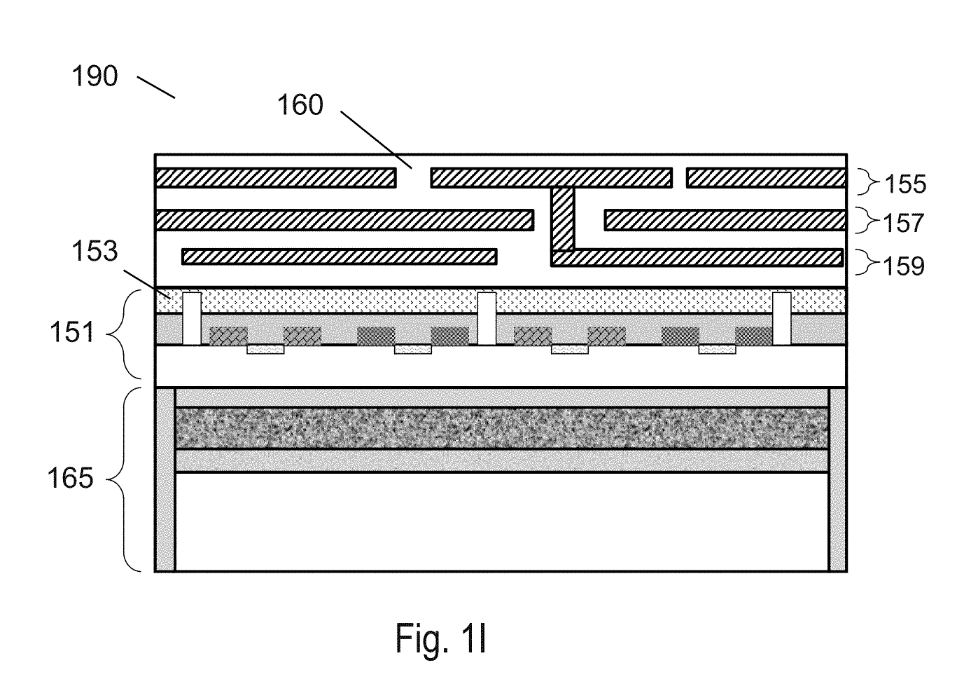

As illustrated in FIG. 1A, a donor wafer 110 may be constructed. Lower porous layer 112 and upper porous layer 114 may be formed by means of anodization on a substrate 100 such as silicon wafer. The anodization process may involve passing a current through a solution of HF and ethanol with the single-crystal silicon wafer as the anode in order to form microscopic pores of diameters of a few nm on the surface of the wafer at a density of about 10¹¹/cm². The reaction occurs at the far end of the pores, meaning that the pores progressively elongate into the inside of the wafer. The structure of the porous silicon can be controlled by the concentration of the solution, the current density and the resistivity of the silicon. Moreover, the thickness of the porous silicon layer can be controlled by the length of time for which the anodization is carried out. The easiest way of controlling the porous structure is to vary the current density. By doing this a porous layer that has a multi-layered structure, for example, lower porous layer 112 and upper porous layer 114, may be formed. In this example, the layer of porous silicon closest to the top surface, upper porous layer 114, was formed in the base silicon wafer using a low current density, and then after this the current density was raised and a second layer of different/higher porosity was formed (lower porous layer 112). The upper layer of porous silicon upper porous layer 114 contains microscopic pores of diameter a few nm, and below this is formed lower porous layer 112 for which the pore diameter is a few times greater than the upper porous layer 114.

Dry oxidation of the porous silicon may be carried out at a low temperature of about 400° C. This results in oxidization of about 1˜3 nm of the inner walls of the pores, thus preventing the structure of the porous silicon from changing, such as bending or relaxing for example, under a subsequent high-temperature treatment.

Baking may be carried out at about 1000˜1100° C. in a hydrogen atmosphere in a CVD epitaxial reactor. Hydrogen pre-baking causes the pores in the porous silicon surface to close up to the extent that the density of these pores goes down from about 10¹¹/cm² before—picture in FIG. 24 of incorporated application Ser. No. 14/642,724—to less than 10⁴/cm², and hence the surface is smoothed. To reduce defects, a pre-injection method could be used whereby a small additional amount of silicon is provided from the gas phase (for example as silane) during the hydrogen pre-baking and surface diffusion is made to occur so that the remaining pores in the surface of the porous silicon close-up.

After the pre-injection, epitaxial growth may be carried out at temperatures of about 900˜1000° C. The epitaxial layer illustrated as epi layer 120 in FIG. 1B could be grown to a few nm thick layer, for example, such as about 5 nm or about 10 nm; or to a moderately thick layer, such as, for example, about 100 nm or about 200 nm; or to a relatively thick layer, such as, for example, about 1 micron, or about 3 microns thick. The donor wafer 110 would then have a silicon layer, epi layer 120, on top of a cut structure 132. Cut structure 132 may include the porous layers, such as lower porous layer 112 and upper porous layer 114. Epi layer 120 may be monocrystalline silicon. Cut structure 132 may include more than 2 layers (for example three differing pore densities) or may be accomplished by a single layer of changing characteristics, for example, a linearly (or non-linear) changing porosity, or a combination of both. Donor wafer 110 may include substrate 100, epi layer 120 and cut structure 132, which may include lower porous layer 112 and upper porous layer 114. The process may also be modified to leave an edge pore exclusion zone (not shown) including and back from the wafer edge that would not receive the anodization and thereby result in no pores being formed. This could be useful for at least mechanical strength, sealing, selectivity objectives. The edge pore exclusion zone may include widths of 1 um to 5 mm and may include/cover the wafer edge, or be pulled back from the edge. The edge pore exclusion zone may also be designed to not be a continuous ring around the wafer's edge, but rather include breaks/regions in the pore exclusion zone ring of porous silicon to improve the future cleaving process, giving direct or near-direct pore access from the wafer edge at select points/regions/cross-sections, which may result in fewer defects.

Donor wafer 110 may be constructed in an alternate manner and resultant structure than presented in FIG. 1B. As illustrated in FIG. 1C, an epi-Si buffer layer 116 may be formed on top of cut structure 132. Cut structure 132 may include the porous layers, such as lower porous layer 112 and upper porous layer 114. Then a SiGe etch-stop reference layer 118 may be formed, for example, by continuing and adjusting the previous epitaxial deposition, and then epi layer 120 may be formed on top of SiGe etch-stop reference layer. Epi layer 120 could be grown to a few nm thick layer, for example, such as about 5 nm or about 10 nm; or to a moderately thick layer, such as, for example, about 100 nm or about 200 nm; or to a relatively thick layer, such as, for example, about 1 micron, or about 3 microns thick. Epi layer 120 may be monocrystalline silicon. Cut structure 132 may include more than 2 layers (for example three differing pore densities) or may be accomplished by a single layer of changing characteristics, for example, a linearly (or non-linear) changing porosity, or a combination of both. Donor wafer 110 may include substrate 100, epi layer 120 and cut structure 132, which may include lower porous layer 112 and upper porous layer 114. The process may also be modified to leave an edge pore exclusion zone (not shown) including and back from the wafer edge that would not receive the anodization and thereby result in no pores being formed. This could be useful for at least mechanical strength, sealing, selectivity objectives. The edge pore exclusion zone may include widths of 1 um to 5 mm and may include/cover the wafer edge, or be pulled back from the edge. The edge pore exclusion zone may also be designed to not be a continuous ring around the wafer's edge, but rather include breaks/regions in the pore exclusion zone ring of porous silicon to improve the future cleaving process, giving direct or near-direct pore access from the wafer edge at select points/regions/cross-sections, which may result in fewer defects. SiGe etch-stop reference layer 118 may be utilized in follow-on process flow steps as an etch stop (and may be conventionally removed with a selective SiGe wet or dry etch), thereby resulting in a layer transfer of a well-known, controlled, and across the wafer controlled thickness and quality monocrystalline silicon layer. This may lower transistor and other device electrical and physical variability when formed by utilizing epi layer 120. As well, the silicon layer transferred may not require any CMP, oxidation, or annealing cleanups or planarization steps to provide a defect free and thickness controlled layer of monocrystalline silicon. Donor wafer 110 of FIG. 1C may be utilized for layer transfer of monocrystalline silicon layer to form many of the monolithic 3DIC structures formed herein and at least within the incorporated references.

In some applications it might be desirable to use the modified ELTRAN process for the fabrication of a 3D device with multiple layers of crystals. The following flow is additional alternative and shares some common flow elements to the flow presented in U.S. patent application Ser. No. 14/642,724 as related to FIGS. 22 to 29. The flow herein utilizes donor wafer 110, but other types of donor wafers may be utilized due to various engineering choices.

As illustrated in FIG. 1D, donor wafer 110 may go through front line processing of at least epi layer 120 to construct at least N type transistors 138 and P type transistors 139 and shallow trench isolations—STI 137, in between the transistors. Other devices (not shown), such as diodes, capacitors, resistors, may be constructed/formed as well. These devices and structures may be processed and formed with conventional semiconductor processing. Thus the devices of Stratum-3 133 may be formed. At the point all the elements on the transistor side of Stratum-3 133 which needs high temperature (>400 C) for their formation could be processed, for example, such as gate oxidation, dopant activation, and silicidation for transistor contacts and LDD.

As illustrated in FIG. 1E, the devices of Stratum-3 133 may be covered with dielectric 142 preparing the Stratum-3 layer transfer structure 150 for a step of layer transfer. Dielectric 142 may include one or many materials and layers, for example, silicon oxides, porous silicon oxides, doped or undoped and/or carbon doped silicon oxides. Additional layer transfer and bonding preparation steps may be done, for example, planarizing dielectric 142 with CMP, treating the dielectric surface with a plasma, etc.

As illustrated in FIG. 1F, Stratum-3 layer transfer structure 150 may be flipped and bonded to improved carrier wafer 165, which may be prepared in similar way as the carrier wafer 2965 illustrated in FIG. 29A of U.S. patent application Ser. No. 14/642,724. (Accordingly for the processing of the carrier wafer 2801 after forming the porous layers 2802 and 2804 the step of forming the oxide bonding layer 2806, oxide 2956 will include covering the carrier wafer side walls with oxide 2958 as illustrated in FIG. 29A. The improved carrier wafer 2951 is now ready for the transfer of the donor layer.) Improved carrier wafer 165 may include a process modification to leave an edge pore exclusion zone (not shown) including and back from the wafer edge that would not receive the anodization and thereby result in no pores being formed. This could be useful for at least mechanical strength, sealing, selectivity objectives. The edge pore exclusion zone may include widths of 1 um to 5 mm and may include/cover the wafer edge, or be pulled back from the edge. The edge pore exclusion zone may also be designed to not be a continuous ring around the wafer's edge, but rather include breaks/regions in the pore exclusion zone ring of porous silicon to improve the future cleaving process, which may result in fewer defects.

As illustrated in FIG. 1G, the bulk of Stratum-3 layer transfer structure 150 may be split off leveraging cut structure 132 while improved carrier wafer 165 may be protected by its side walls 168, or some other mechanism/structure, for example, the pore edge exclusion zone described herein. Thus forming Stratum-3 151, which is attached to improved carrier wafer 165. The dual porous layers helps to achieve a very clean split as the border between the two porous layers tends to be a natural cut-plane. The residue of porous structure could be cleaned off by, for example, an etch, such as, by using a solution containing a mixture of HF, H₂O₂ and H₂O. Once a certain incubation period has passed, the porous silicon is etched virtually all at once. The selectivity of this etching may be as high as 100,000×, meaning that the etching does not cause significant degradation of the uniformity of the thickness of the remaining layer. This means that the bulk of Stratum-3 layer transfer structure 150 could be recycled for reuse and Stratum-3 151 is now ready for future processing. It should be noted that these illustrations are not presenting the layers in thickness proportion. Both the donor wafer 110 and improved carrier wafer 165 may be about 700 μm thick. The Stratum-3 151 layer may be a few tens of nm to a few microns thick depending on the choice of process line and other considerations.

As illustrated in FIG. 1H, depending on design, device and process integration choices and considerations, some optional back side processing of Stratum-3 151 may be done. These back side structures are illustrated by S3 backside layer 153 and may include, for example, back bias or back gates of strata-3 devices, heat spreader, emf shield, etc.

As illustrated in FIG. 1I, back-side interconnections may be processed and formed on top of S3 backside layer 153 (shown) or Stratum-3 151 (not shown). These interconnection layers could use refractory metal such as tungsten so that they could withstand following steps of high temperatures (>400 C). These interconnections could include, for example, local connections for Stratum-3 159, power distribution on optional shielding 157, and local interconnection 155 for future Stratum-2. Inter-metal dielectric 160 may include low k dielectrics and conventional silicon oxide depending on future temperature exposure process integration choices. Thus Stratum-3 processed structure 190 may be formed. Stratum-3 processed structure 190 may include local connections for Stratum-3 159, power distribution on optional shielding 157, local interconnection 155, Inter-metal dielectric 160, S3 backside layer 153, Stratum-3 151, and improved carrier wafer 165.

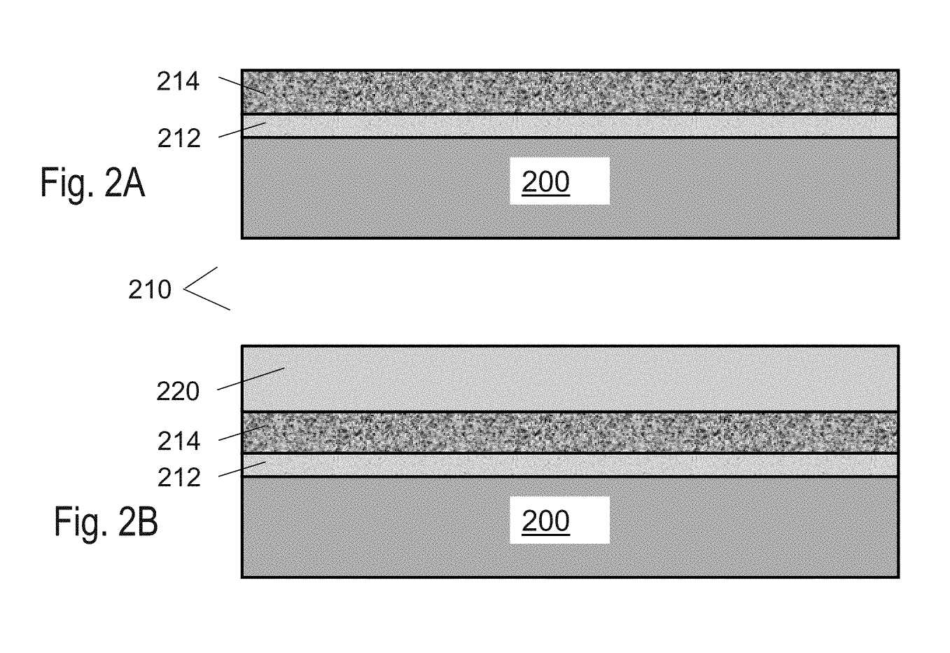

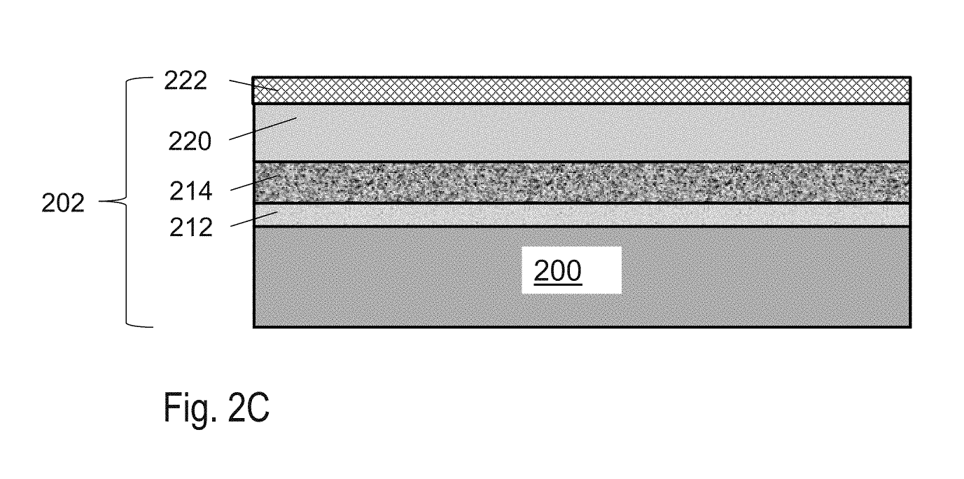

As illustrated in FIG. 2A, a Stratum-2 donor wafer 210 may be prepared by forming lower porous layer 212 and upper porous layer 214 on S2 substrate 200. The formation processing and structure may be done similarly to the donor wafer 110 herein above.

As illustrated in FIG. 2B, S2 epitaxial layer 220 may be formed on top of upper porous layer 214. The formation processing and structure may be done similarly to the donor wafer 110 herein above.

As illustrated in FIG. 2C, depending on design, device and process integration choices and considerations, some optional processing of S2 epitaxial layer 220 may be done. These back side structures are illustrated by S2 backside layer 222 and may include, for example, back bias or back gates of strata-2 devices, heat spreader, emf shield, etc. Thus, stratum-2 layer transfer structure 202 may be formed and may include S2 backside layer 222, S2 epitaxial layer 220, upper porous layer 214, lower porous layer 212 and S2 substrate 200. Layer transfer and bonding preparation steps may be done.

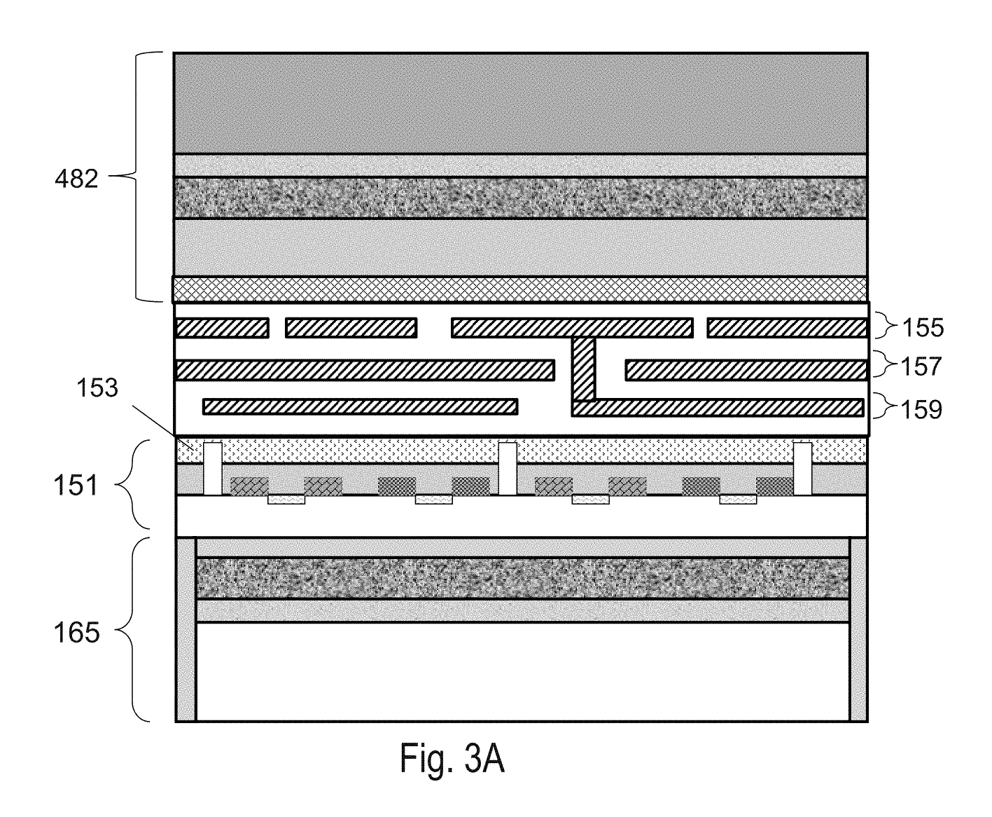

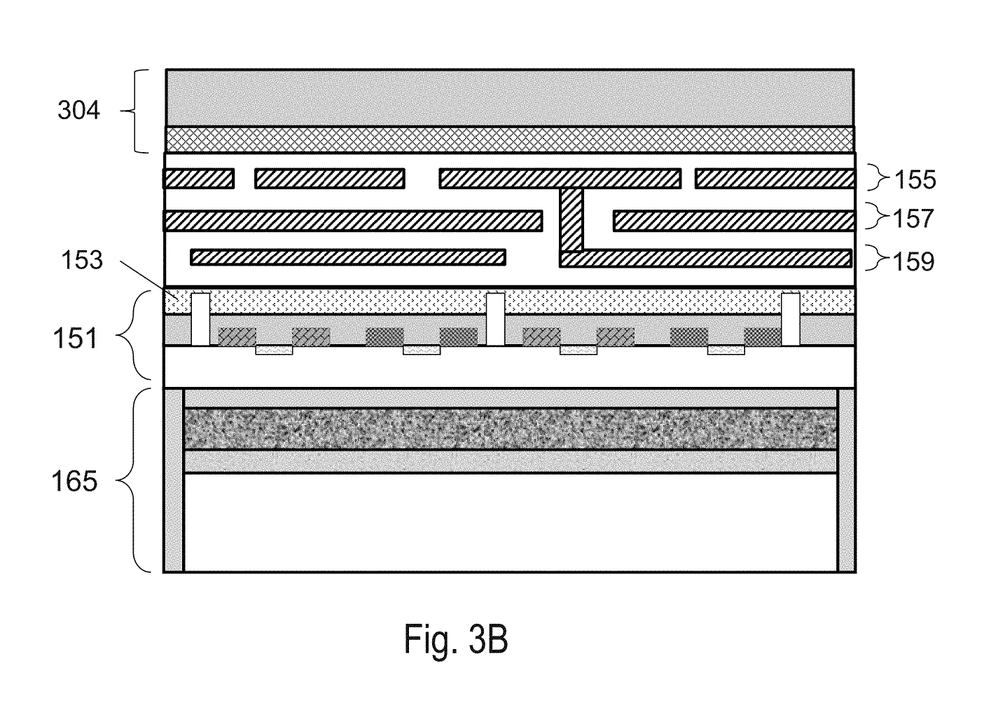

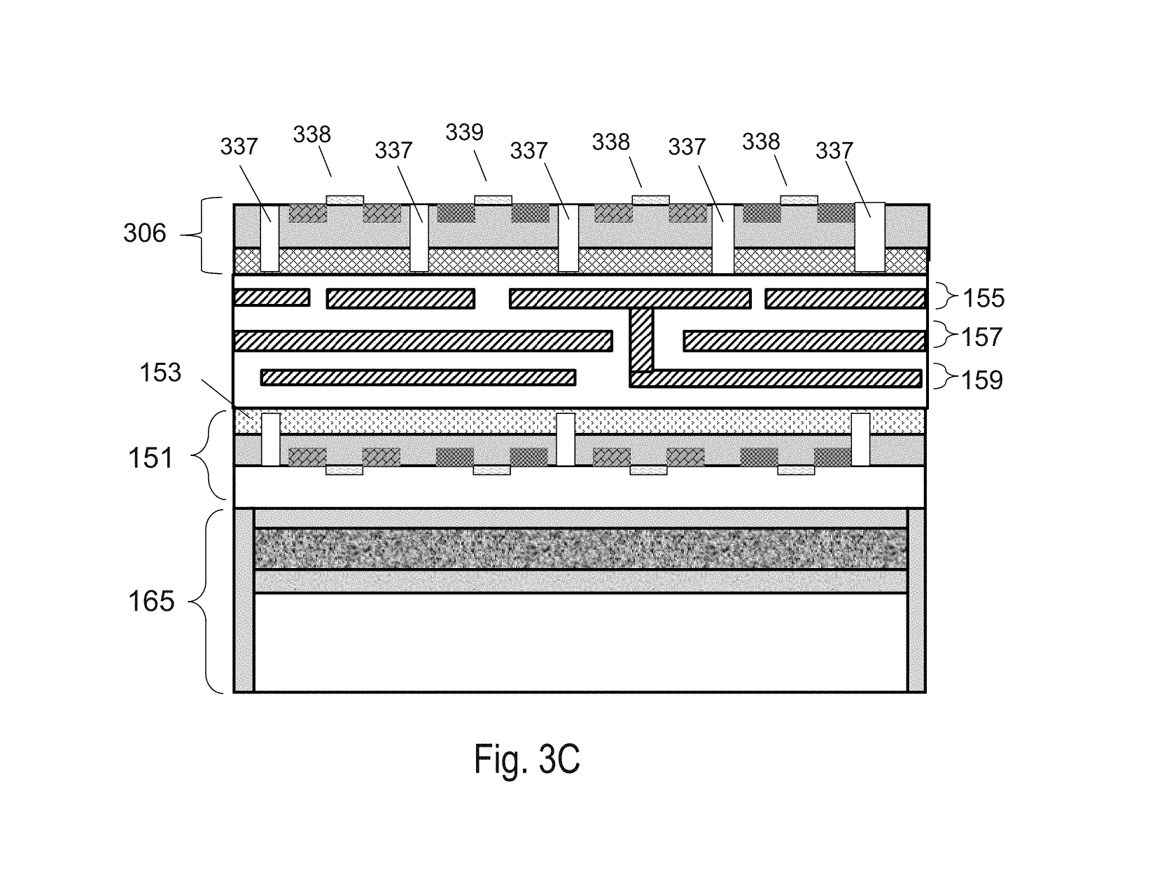

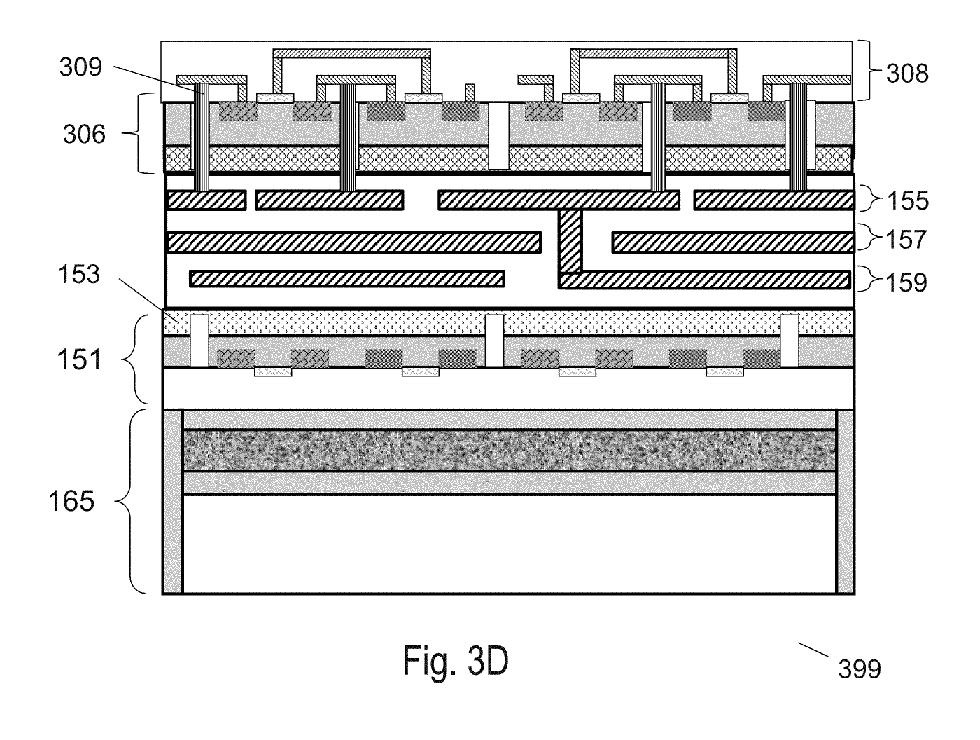

As illustrated in FIG. 3A, stratum-2 layer transfer structure 202 may be flipped and on top of the Stratum-3 processed structure 190. Bonding and isolation oxide layers may be utilized for the bonding (not shown).

Alternatively the donor wafer, for example stratum-2 layer transfer structure 202, could be processed for ion-cut layer transfer technology rather than with a ‘Modified ELTRAN’ technology. In such case instead of the porous layers and epitaxial deposition, an implant of H+ or other ion or combination of ions (described in detail in at least incorporated reference U.S. Pat. No. 8,273,610) could be used to form a cut layer of ion damage in replacement of the porous cut layers upper porous layer 214, lower porous layer 212. An advantage of combining two types of ‘cut’ layers—porous and ion—is the ease in selecting which layer would get cut at which point of the process flow. For example, in the case of the structure of FIG. 3A, the cut of the donor wafer stratum-2 layer transfer structure 202 would be done by heating the entire structure to a temperature between 500° C.-800° C., thereby splitting at or near the ion-cut damage layer but not affecting porous layers of the underneath donor wafer improved carrier wafer 165. Since the structure of FIG. 3A does not include copper or aluminum interconnection layers such an alternative could be easily adapted. Furthermore, improved carrier wafer 165 may not require the extra processing to ‘improve’ it, sidewalls 168. Moreover, the donor wafer 110, with an integrated SiGe etch stop reference layer, may be utilized.

As illustrated in FIG. 3B, the bulk of stratum-2 layer transfer structure 202 may be split off leveraging lower porous layer 212 and upper porous layer 214. S2 substrate 200 may be recycled for further use. Cleaning of the porous residues and smoothing of the epi surface may be performed. Thus S2 layer 304 remains. S2 layer 304 may include a substantial portion or substantially all of S2 epitaxial layer 220, and may include S2 backside layer 222. Other layer transfer techniques such as ion-cut could alternatively be used to form S2 layer 304 as the use of higher than 400° C. is acceptable.

As illustrated in FIG. 3C, S2 layer 304 may go through front line processing of at least S2 epitaxial layer 220 to construct at least N type transistors 338 and P type transistors 339 and shallow trench isolations—STI 337, in between the transistors, thus forming Stratum-2 306. Other devices (not shown), such as diodes, capacitors, resistors, may be constructed/formed as well). These devices and structures may be processed and formed with conventional semiconductor processing. Thus the devices of Stratum-2 306 may be formed. At the point all the elements on the transistor side of Stratum-2 306 which needs high temperature (>400 C) for their formation could be processed, for example, such as gate oxidation, dopant activation, and silicidation for transistors contacts and LDD. Stratum-2 structures could be aligned to the interconnection underneath and/or Stratum-3 using lithography alignment marks as these layers are thin enough for the stepper/aligner to see thru at short wavelength light, thus allowing state of the art alignment; for example, alignment of Stratum-2 and Stratum-3 devices and structures to less than about 2 nm, to less than about 4 nm, to less than about 8 nm, to less than about 10 nm. In some cases there might be concern in respect to the effect on the thermal budget of Stratum-3 from the high temperature process associated with forming Stratum-2. Using lasers, for example excimer lasers, for the Stratum-2 high temperature steps and proper shielding such as optional shielding 157 could help to reduce the negative impact on Stratum-3 transistors. Variations of processing techniques to allow high temperatures processing of Stratum-2 while reducing the effect on the underling structure such as Stratum-3, for example, using such shielding layer were presented in more detail in U.S. Pat. Nos. 9,023,688 and 8,574,929, incorporated herein by reference.

As illustrated in FIG. 3D, stratum-2 through layer vias 309 and interconnect layers 308 may be formed. Copper or aluminum could be used to provide the conductive interconnection. Stratum-2 through layer vias 309 may pass thru Stratum-2 306 and electrically and thermally couple devices in Stratum-2 306 (for example N type transistors 338 and P type transistors 339) to local interconnection 155. Later in the processing, stratum-2 through layer vias 309 may enable electrically and/or thermally coupling of devices on Stratum-2 306 (for example N type transistors 338 and P type transistors 339) to devices of Stratum-3 151 (for example N type transistors 138 and P type transistors 139), which may be considered thermally conductive paths and/or electrically conductive paths. Thus dual strata donor structure 399 is formed. Dual strata donor structure 399 may include improved carrier wafer 165, Stratum-3 151, S3 backside layer 153, local interconnection 155, optional shielding 157, local connections for Stratum-3 159, Stratum-2 306, stratum-2 through layer vias 309 and interconnect layers 308.

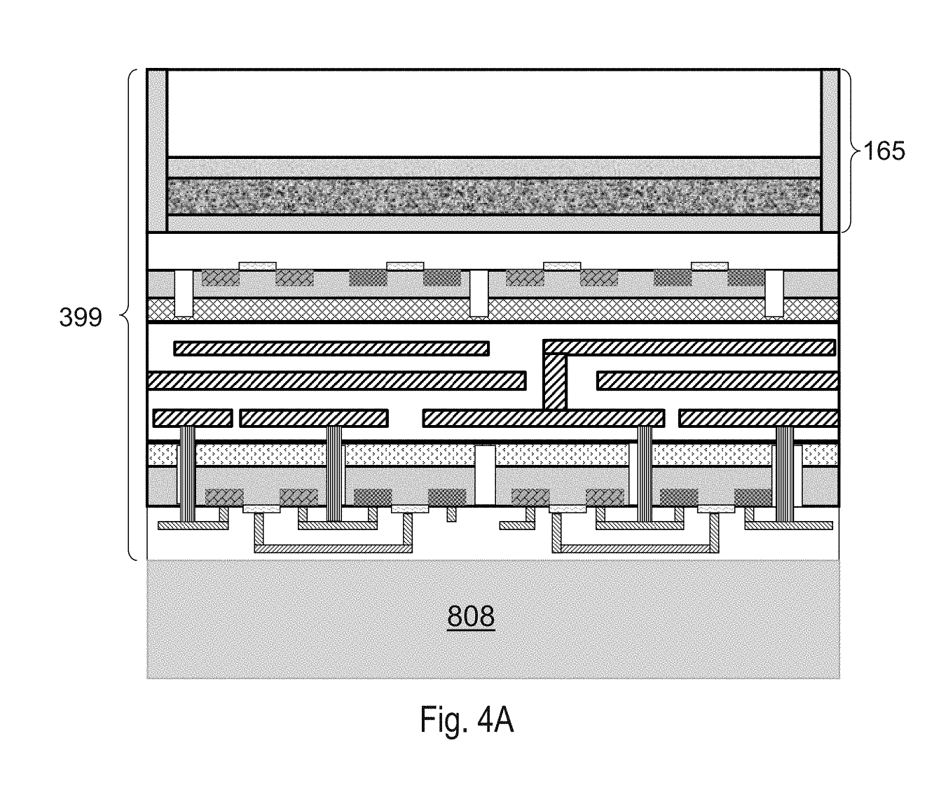

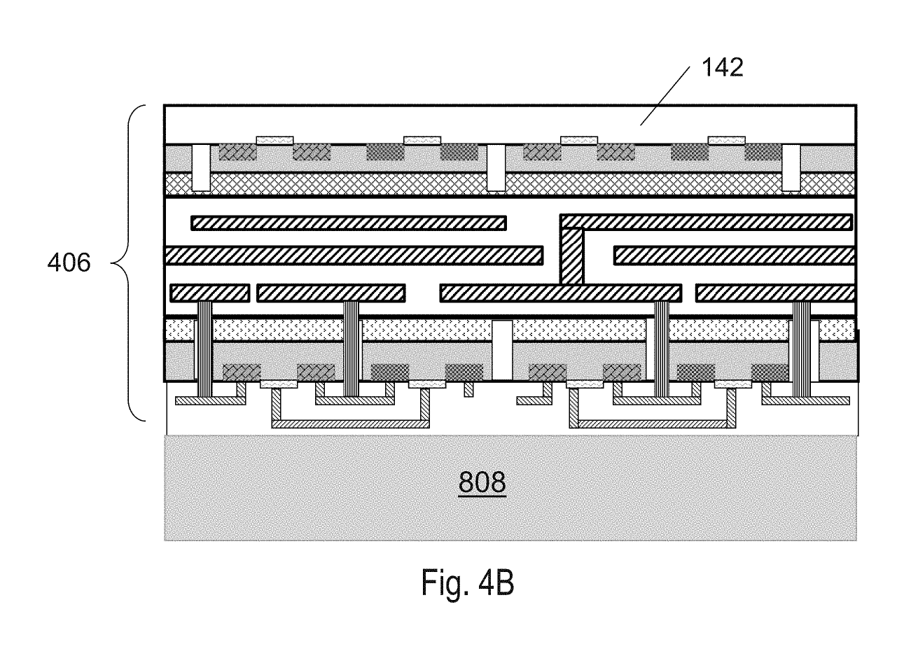

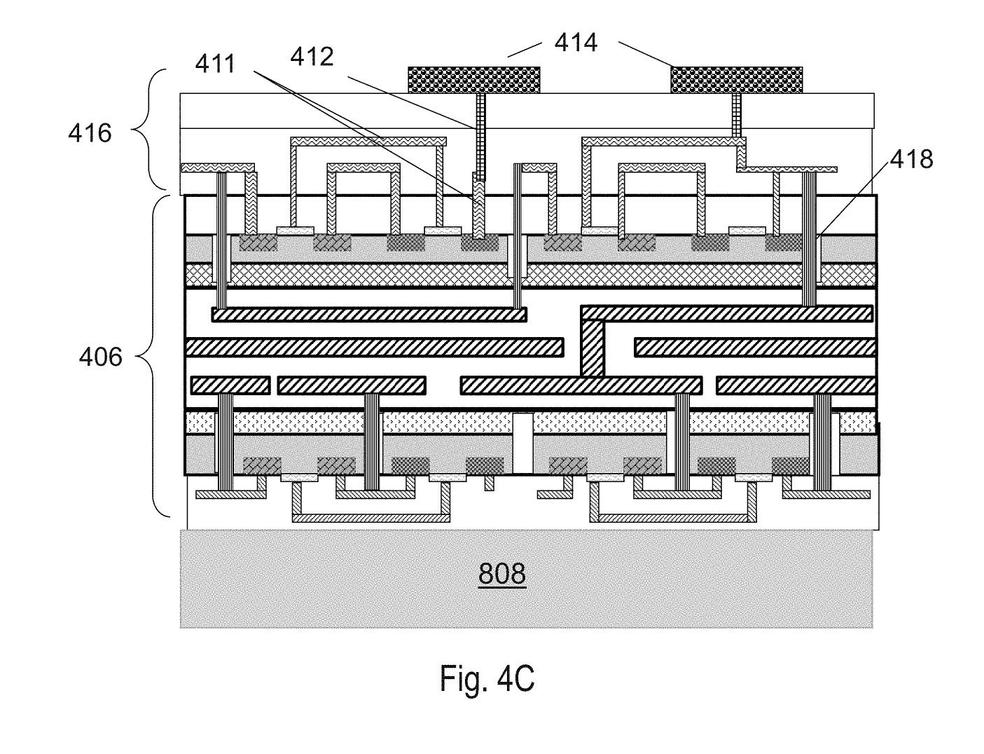

As illustrated in FIG. 4A, dual strata donor structure 399 may be flipped and bonded on top of a target carrier or wafer 808. Description of target wafer/substrate 808 may be found in at least referenced U.S. Pat. No. 8,273,610. Bonding and isolation oxide layers may be utilized for the bonding (not shown).

As illustrated in FIG. 4B, the bulk of improved carrier wafer 165 may be split off leveraging lower porous layer 112 and upper porous layer 114. Substrate 100 may be recycled for further use. Cleaning of the porous residues and smoothing of the epi surface may be performed. As well, the top epi layer may be removed. Thus dual strata structure 406 is formed and continues to be attached to target wafer/substrate 808. Dielectric 142 may be exposed on top of the structure after cleaning. In some applications, such as image sensors, there might be no need to add interconnection to Stratum-3.

As illustrated in FIG. 4C, connection layer 416 may be formed. Connection layer 416 may include S3 through layer vias 418 for connecting Stratum-3 to the back side interconnects, Stratum-3 interconnects 411, pads 414 for connection to other device and the pad to S3 interconnects 412 for connection of these pads 414 to Stratum-3 interconnects 411. Dual strata structure 406 devices may be electrically and/or thermally connected to the devices and structures of target wafer/substrate 808 (not shown), as described in the incorporated references. Dual strata structure 406 may include a layer/regions of transistors facing upwards and a layer/regions of transistors facing downwards.

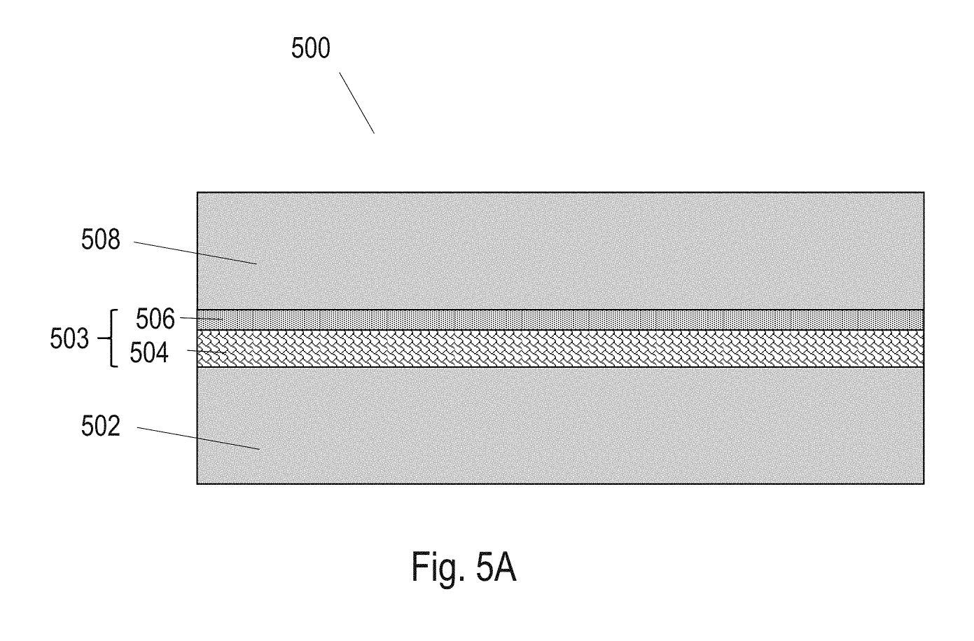

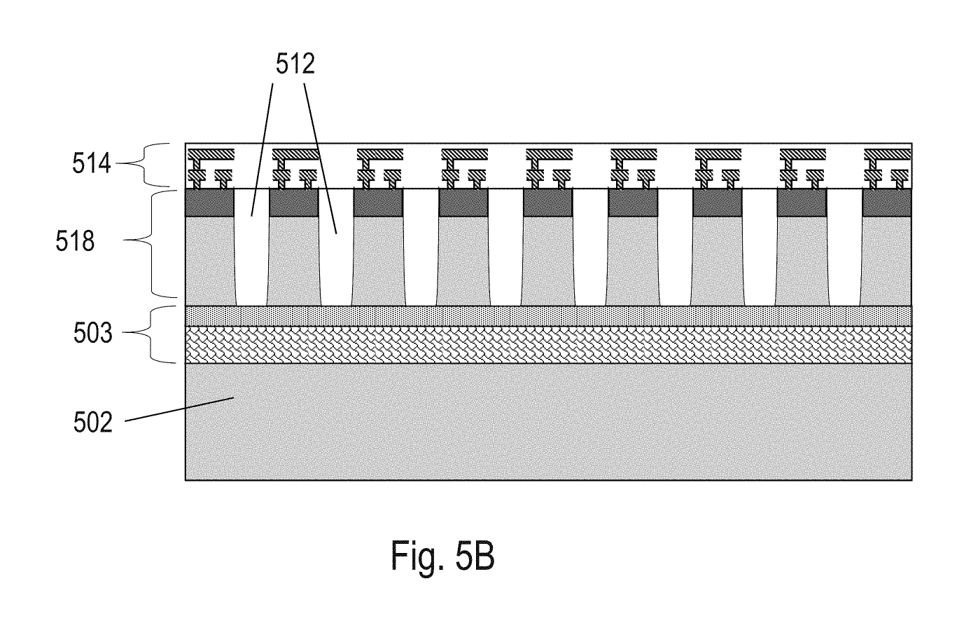

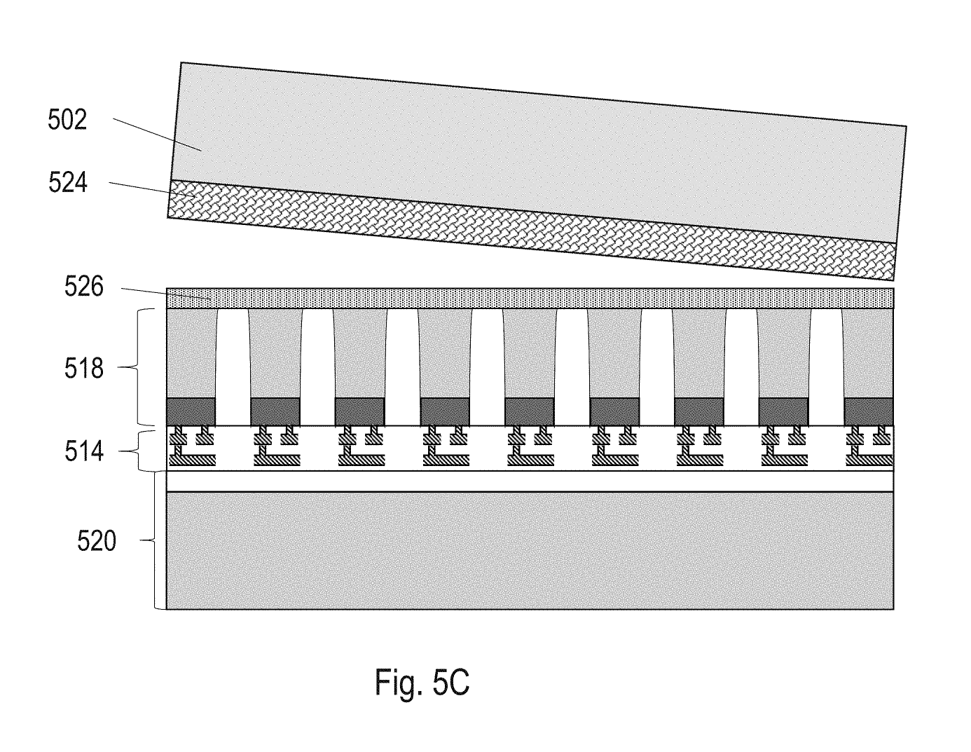

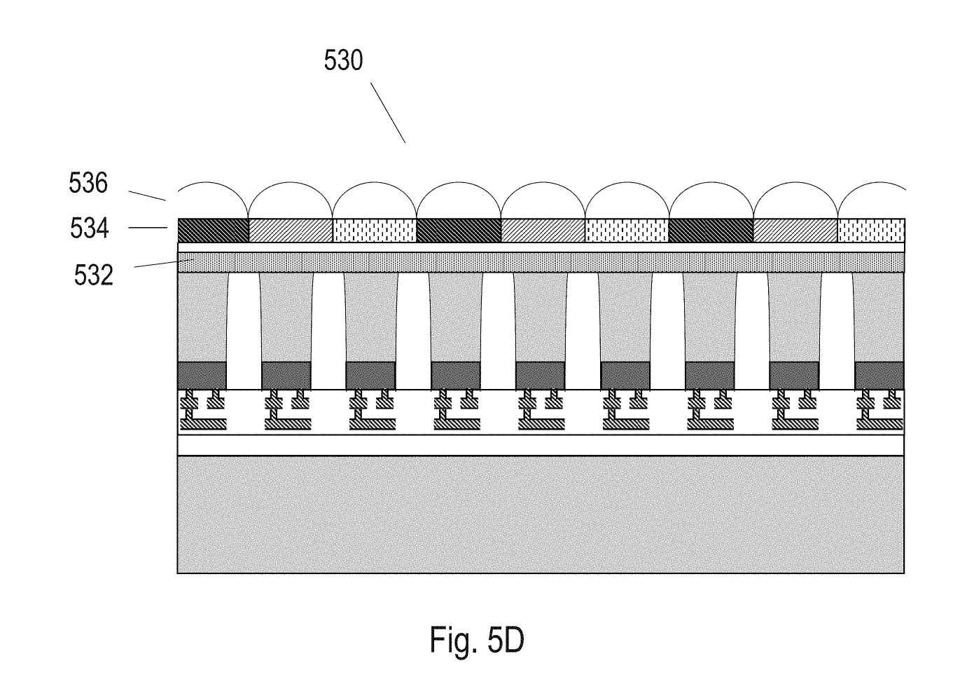

Back illumination image sensors have become popular as they allow most of the light to reach the photo detector sensor region(s). The porous ‘cut’ layer could be used for simplifying the fabrication of back side illuminated (BSI) image sensor as illustrated in FIGS. 5A-5D.

As illustrated in FIG. 5A, donor wafer 500 may be formed and may include base silicon 502 on top of two layers of porous silicon, lower porous layer 504 and upper porous layer 506 (together called cut layer 503) on top of cut layer 503 may be formed epitaxial layer 508. The construction of such structure was presented herein and including in respect to FIG. 25 of U.S. patent application Ser. No. 14/642,724. Epitaxial layer 508 may include materials such as mono-crystalline silicon, germanium, silicon germanium.

As illustrated in FIG. 5B, donor wafer 500 may be processed to form image sensor pixels 518 on/within epitaxial layer 508. Processing may include etching epitaxial layer 508 such to define individual image sensor pixels—photo diodes, and filling with isolating material forming deep trench isolation 512, thus forming a layer or regions of photosensitive volumes image sensor pixels 518. Alternatively, deep trench isolation 512 may further include a structure (not shown) such as, for example, electrically floating polysilicon, such that incident light may be reflected and may be confined within the pixel. Processing may continue and include contacting the individual image sensor pixels 518, such as photo diodes, and constructing sensor interconnection layer 514. These processing steps are the well-known in the art for the construction of image sensor wafers. A distinction is having the cut layer 503 underneath.

As illustrated in FIG. 5C, the structure of FIG. 5B may be flipped and bonded to a final carrier or a target wafer 520. A cleaving/separating process may utilize cut layer 503 thus donor wafer 502 could be send to be recycled and part of the residues donor residues 524 of the remaining of cut layer 503 could be cleaned off. The other part of the porous residues target residues 526 could be left to support the image sensor to increase light absorbance. The image sensor pixels 518 and sensor interconnection 514 are now flipped and upside-down facing target wafer 520.

As illustrated in FIG. 5D, BSI image sensor 530 may be formed by adding RGB (Red Green Blue) color filters 534 on top of the antireflection layer 532 and adding micro-lenses 536. Anti-reflection layer 532 may include target residues 526.

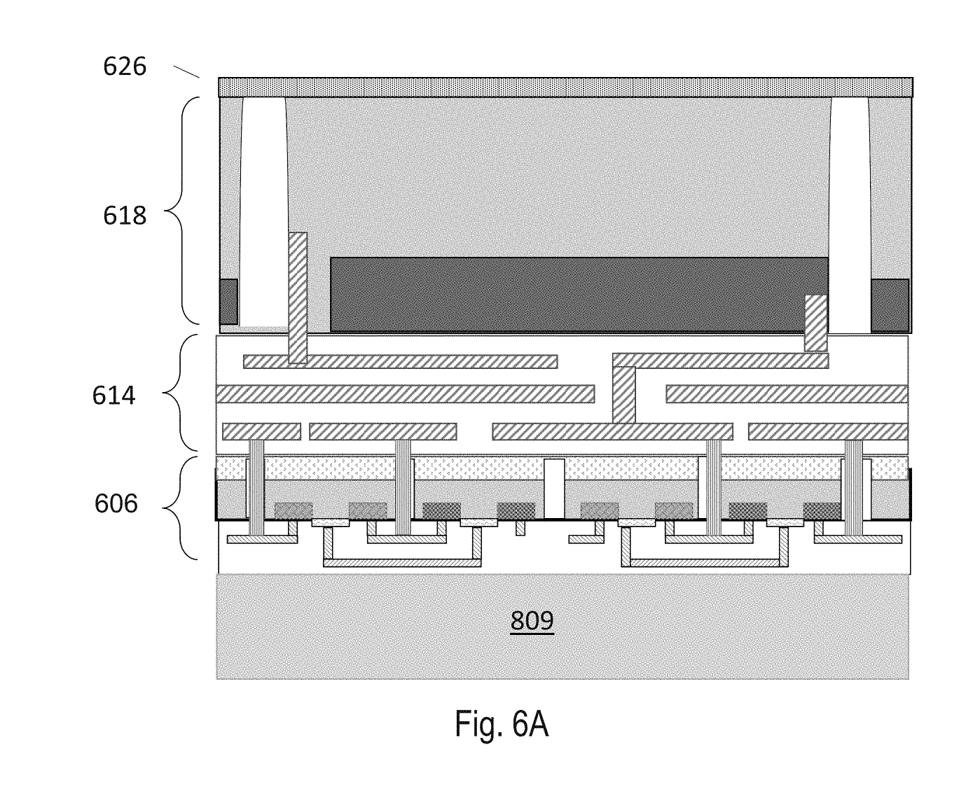

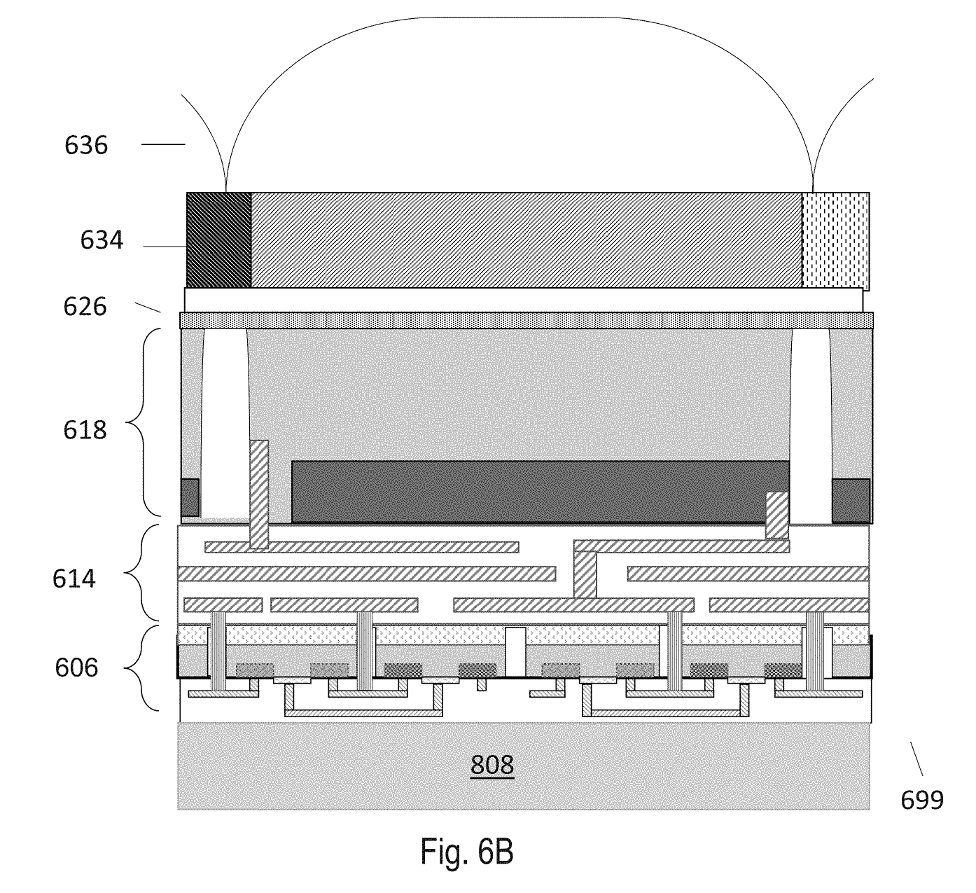

An alternative flow could allow adding some per pixel electronics by adding a second stratum to the image sensor. In provisional application 62/172,079, incorporated herein by reference, a monolithic 3D flow for two stratums is presented in respect to FIGS. 1A to 4B. By modifying the flow first by constructing Stratum 3 151 for image sensor similar to the image sensor 518 illustrated in FIG. 5B, and the interconnect layers 155, 157, 159, similar to the interconnect 514, the structure of FIG. 4B would now look like the structure of FIG. 6.

Accordingly portions of the above flows (such as FIGS. 4 and 5) could be used to construct 3D IC image sensors as illustrated in FIGS. 6A and 6B. As illustrated in FIG. 6A, stratum 2 606 could include the pixel electronics, and may be connected to the image senor pixels using the pixel interconnect 614 to the image sensors diodes 618 (similar to image sensor pixels 518). Image sensors diodes 618 may be covered by antireflection layer 626. Pixel electronics 606 may consist of transfer transistors, reset transistors, select transistors, and/or readout transistors. Alternatively, if desired, pixel electronics 606 may further include other circuit blocks such as data processing, D/A, A/D, etc. This structure (stratum 2 606, pixel interconnect 614, image sensors diodes 618, antireflection layer 626) may be on top of a target wafer/substrate 809 carrying the device electronics. Target wafer/substrate 809 may also be a carrier wafer for further integration processing. Target wafer/substrate 809 may be similar to target wafer/substrate 808 herein.

FIG. 6B illustrates adding the RGB filters 634 and the micro-lenses 636. Thus an integrated 3DIC image sensor with per pixel electronics 699 may be constructed. 3DIC image sensor with per pixel electronics 699 may include target wafer/substrate 808 carrying device electronics, transistors which may be electrically connected (not shown) to Stratum-2 606 (which may include Stratum-2 transistors and devices), pixel interconnect 614 which may electrically couple Stratum-2 606 with image sensors diodes 618, and may further include antireflection layer 626, RGB filters 634 and micro-lenses 636. Stratum-2 606 may have a thickness of about 50 nm, of about 100 nm, of about 200 nm, of about 300 nm, of about 500 nm, of about 1 micron, of about 2 microns. The diameter and/or widths of the metal structures of pixel interconnect 614 may be about 20 nm, about 40 nm, about 60 nm, about 80 nm, about 100 nm, about 200 nm, or about 300 nm. Pixel interconnect 614 may have a thickness of about 50 nm, of about 100 nm, of about 200 nm, of about 300 nm, of about 500 nm, of about 1 micron, of about 2 microns.

An alternative flow could use a modified ELTRAN flow and sacrificial layer such as a porous layer or SiGe layer for the construction of 3D image sensors with pixel electronics and bifacial illumination (Directed absorption and Reflected absorption).

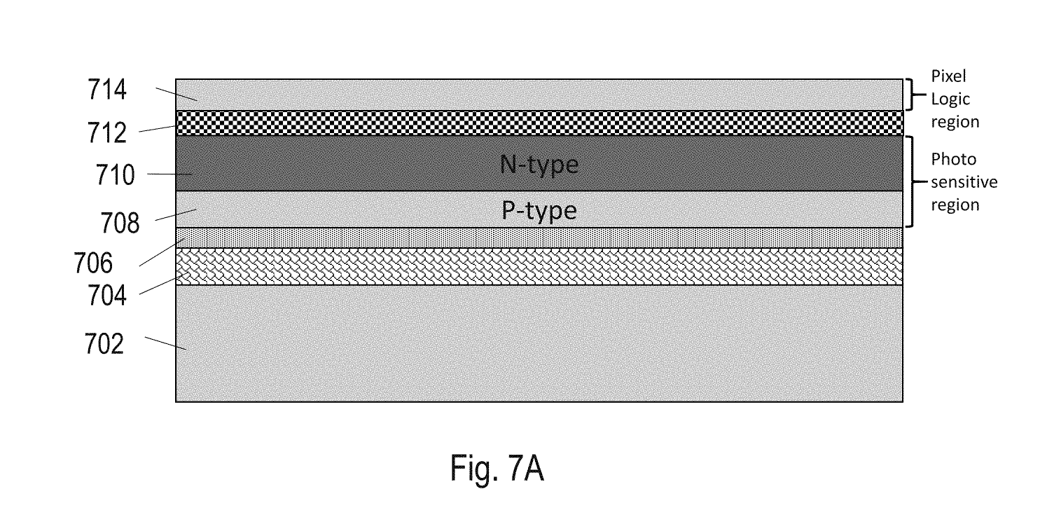

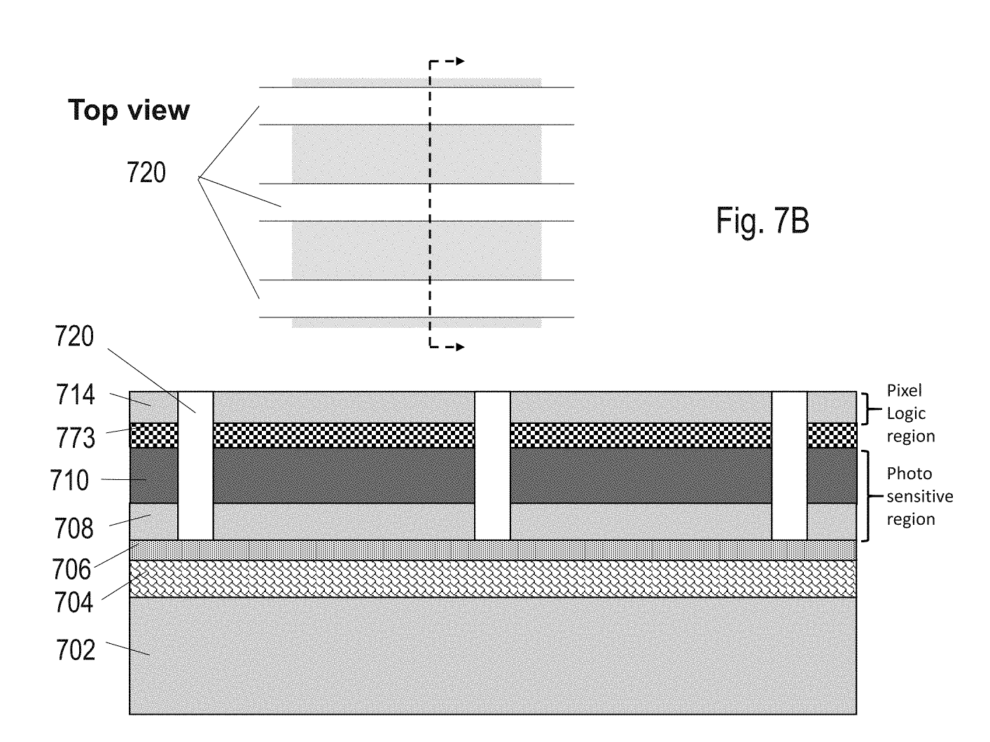

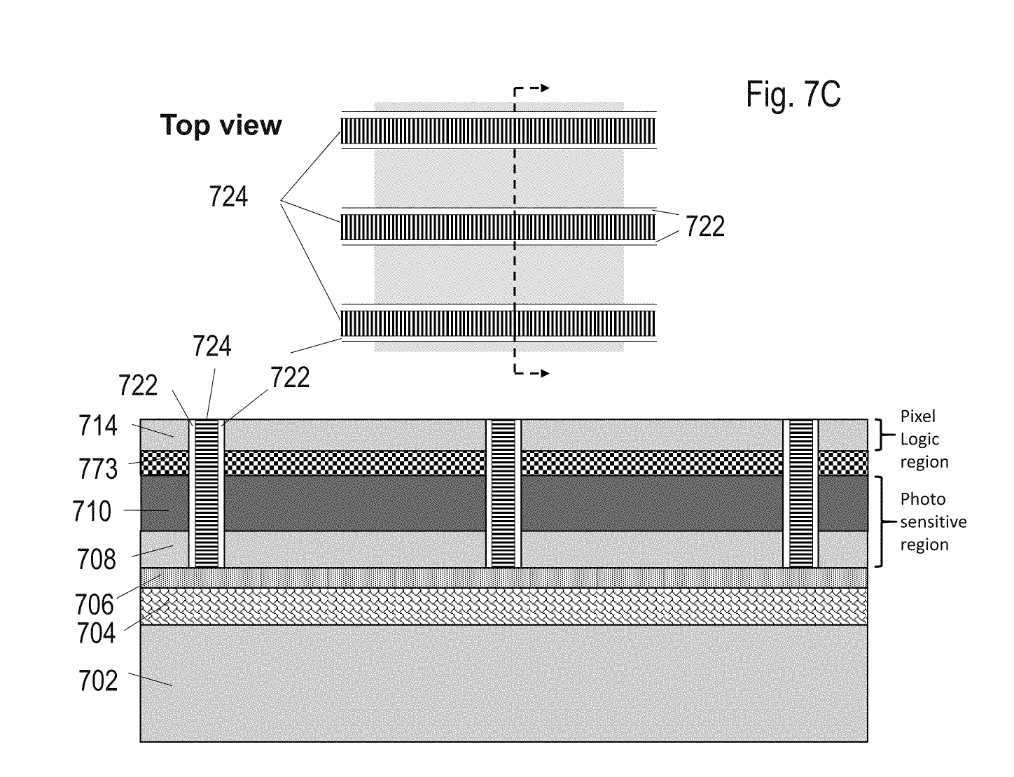

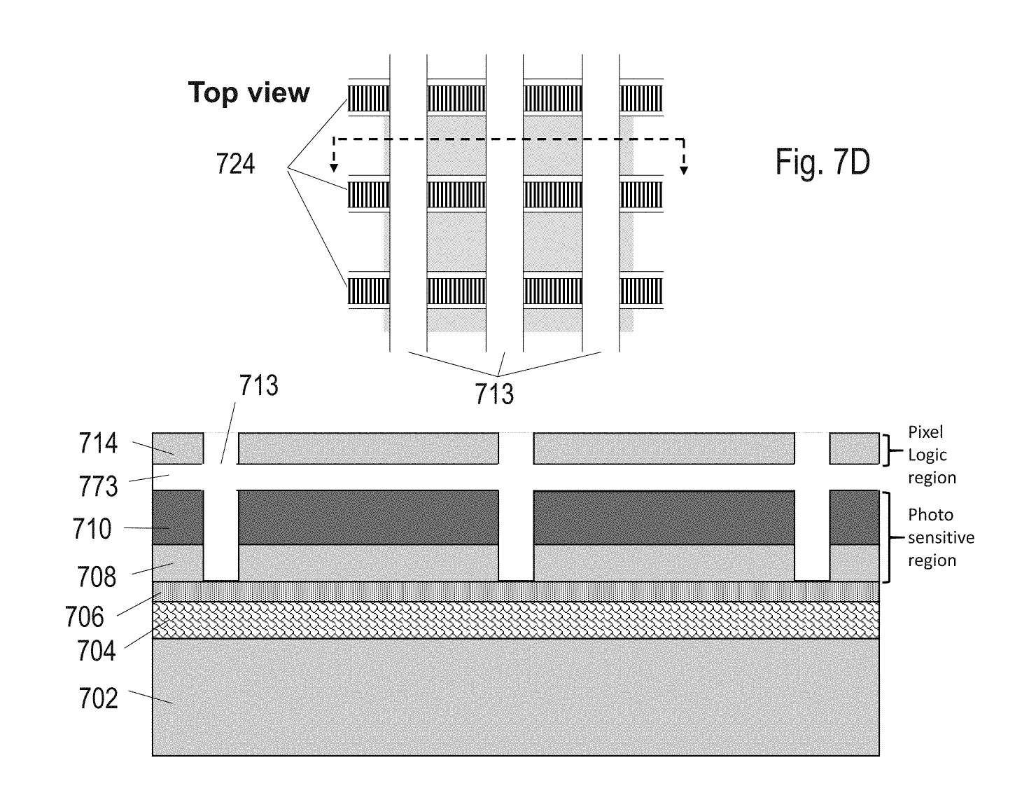

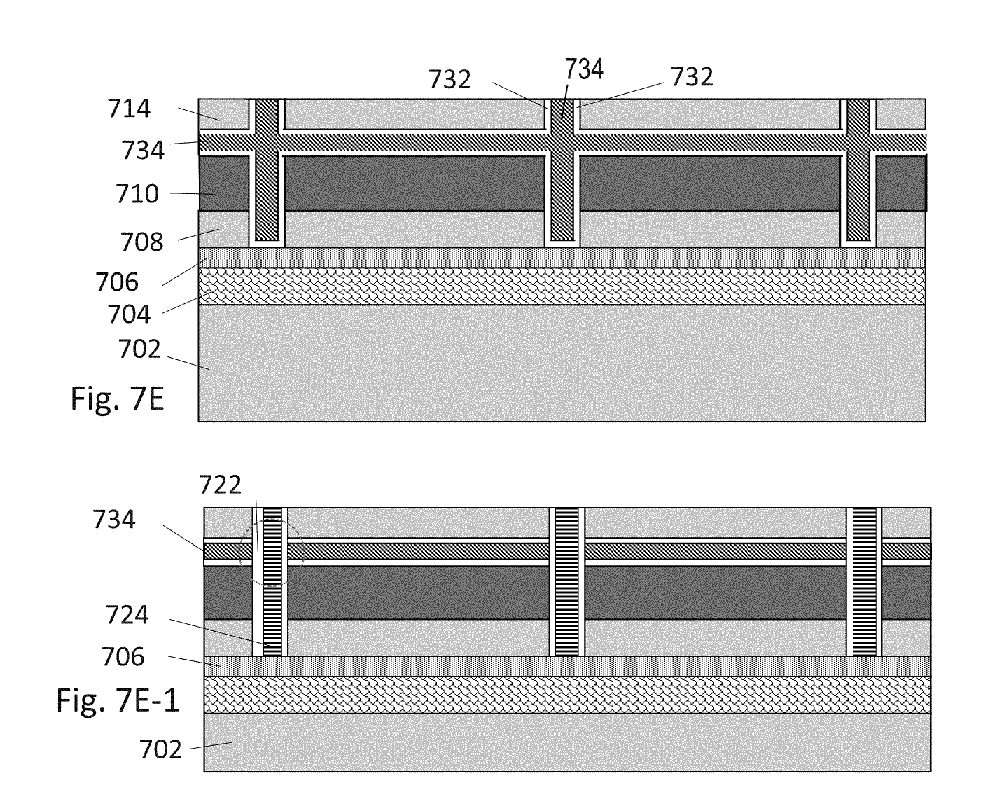

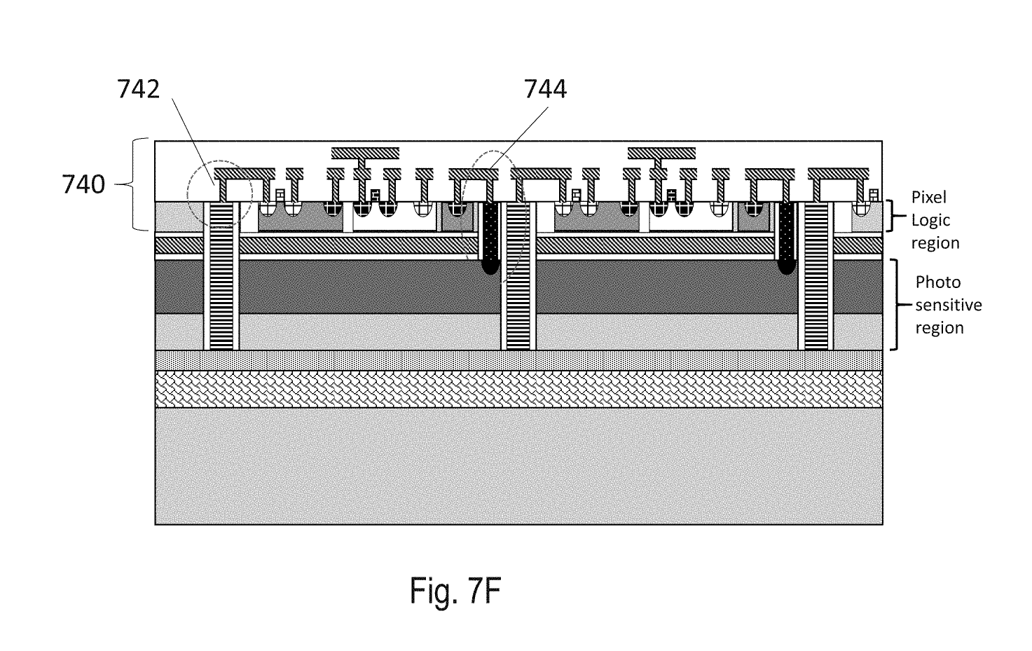

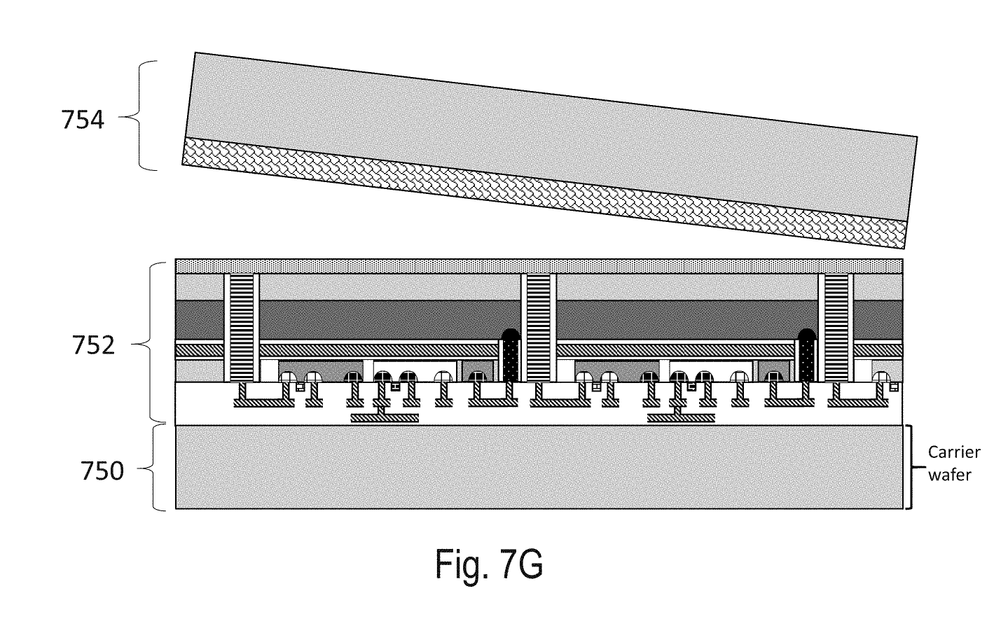

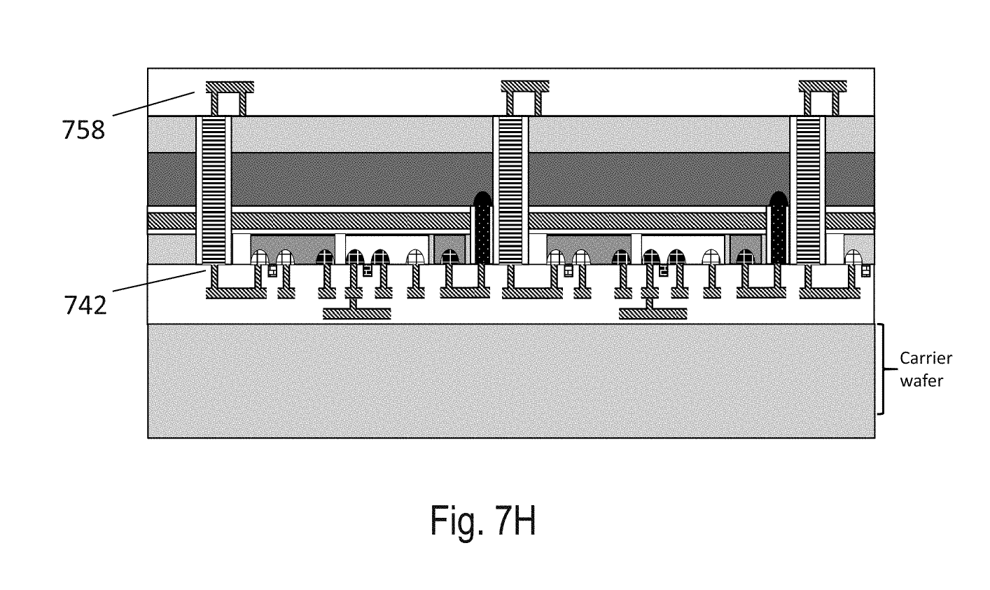

FIG. 7A illustrates a donor wafer 702 with double porous cut layers lower porous layer 704 and upper porous layer 706. Just as been described before, an epitaxial layer could be grown on the upper porous layer 706. The epitaxial layer may be first used to construct the image sensor photo diodes. The anode could be P-type silicon 708, and then the cathode which could be N-type silicon 710. These may be formed by well-known semiconductor processes. A sacrificial layer 712 could then be constructed on top of layer N-type silicon 710. The sacrificial layer 712 could be a porous layer similar to what was presented in provisional application 62/139,636, incorporated by reference herein. Alternatively sacrificial layer 712 could be constructed by continuing the epitaxial layer while adding Germanium to form a SiGe crystalline layer. The important feature of the sacrificial layer 712 is having a good etch selectivity vs. silicon so it could be etched with minimal effect on the silicon layers it borders with. This could help adding a buried mirror to isolate the later processed logic layer and to enhance the image sensor sensitivity. On top of the sacrificial layer 712 an additional layer of P type silicon top 714 could be grown for the pixel electronics construction.

As illustrated in FIG. 7B, rows of pixels may be formed by etching deep trench 720 through the layers P type silicon top 714, sacrificial layer 712, N-type silicon 710, P-type silicon 708 to or slightly into upper porous layer 706. The deep trench 720 may be formed in one direction. These will define rows of pixels.

As illustrated in FIG. 7C, deep trench 720 may be filled (the horizontal lines of these etched rectangles) first by silicon oxide (or other dielectric) forming dielectric side walls 722 and then by doped polysilicon or a refractory metal conductive fill 724 (so it could withstand high temperature steps later). This conductive filling could be used for the pixel interconnection and as mirrors to enhance the image sensor, and as structural anchors of top silicon layers P type silicon top 714 for the etching of the sacrificial layer 712.

As illustrated in FIG. 7D, columns of pixels may be formed by etching another deep trench through the layers P type silicon top 714, sacrificial layer 712, N-type silicon 710, P-type silicon 708 or slightly into upper porous layer 706. The deep trench 713 may be formed in perpendicular direction with respect to the deep trench 720, which results in a rectangular shaped pixel. After the deep trench etching, the sacrificial layer 712 may be selectively removed, thus bottom suspension void 773 may be formed. Due to the previously filled column deep trench isolation 720, the P type silicon top 714 may be anchored and suspended.

FIG. 7E illustrates the structure after filling the sidewall with isolation material such as oxide 732 and then filled-in with doped poly 734. The poly layers 724 and 734 covered by oxide provide pixel isolation side walls and bottom mirrors, optical isolation for the pixel electronics. The poly layer 724 may be further used for pixel interconnects. FIG. 7E-1 illustrates that the poly layer deposited in the horizontal lines of the deep trenches 724 are isolated from the poly lines deposited in the vertical ‘dashed’-lines 734 by the prior deposited oxide isolation, and thus may be separately biased.

As illustrated in FIG. 7F, regions of devices and interconnects, for example pixel electronics with pixel logic regions, may be formed on/in the P type silicon top 714 including transistors, contacts to the image sensor pixels, backside anode contact 742, backside cathode contact 744, thus forming device layer 740.

FIG. 7G illustrates the structure of FIG. 7F flipped and bonded to carrier or target wafer 750, and cutting off the base donor wafer layer 754 leveraging the dual porous cut layers. As presented before the base donor could be cleaned and recycled. Thus, the integrated image sensors and pixel electronics 752 are attached to carrier or target wafer 750.

FIG. 7H illustrates completing the backside anode contact 742, by adding the backside connection to the image sensor diode anode 758. Backside connection to the image sensor diode anode 758 may include aluminum, copper, tungsten conductors.

As illustrated in FIG. 7I, image sensor front optical elements 760 may be formed. Image sensor front optical elements 760 may include antireflection layer 762, Red-Green-Blue (“RGB”) color filters 764, and micro-lenses 766.

Another alternative is a sub-system utilizing monolithic 3D IC, for example, such as been described herein, for the big-data world or what other call ‘abundant data’. While traditional compute systems have been processor centric, there is a growing need for a data centric processor. Such a sub-system could be called Processed Data Device—“PDD”. The PDD could be a useful building block for many compute systems as it could hold a large amount of data but it also could perform operations on the data at high speed and low power as the data and the local processor are at close proximity leveraging the monolithic 3D architecture.

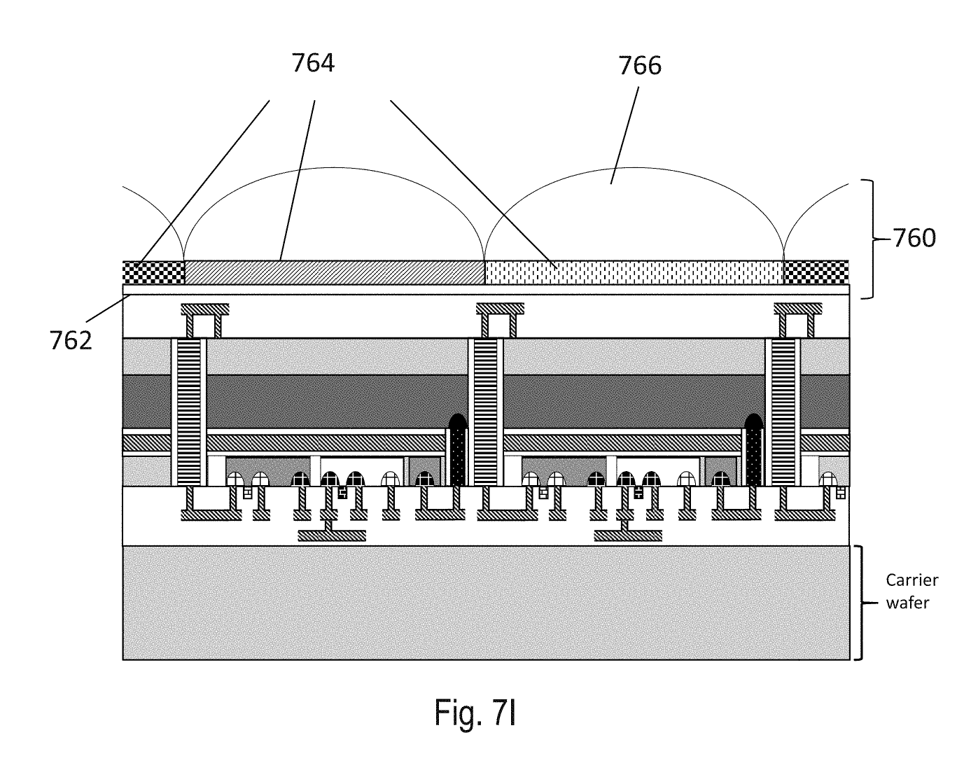

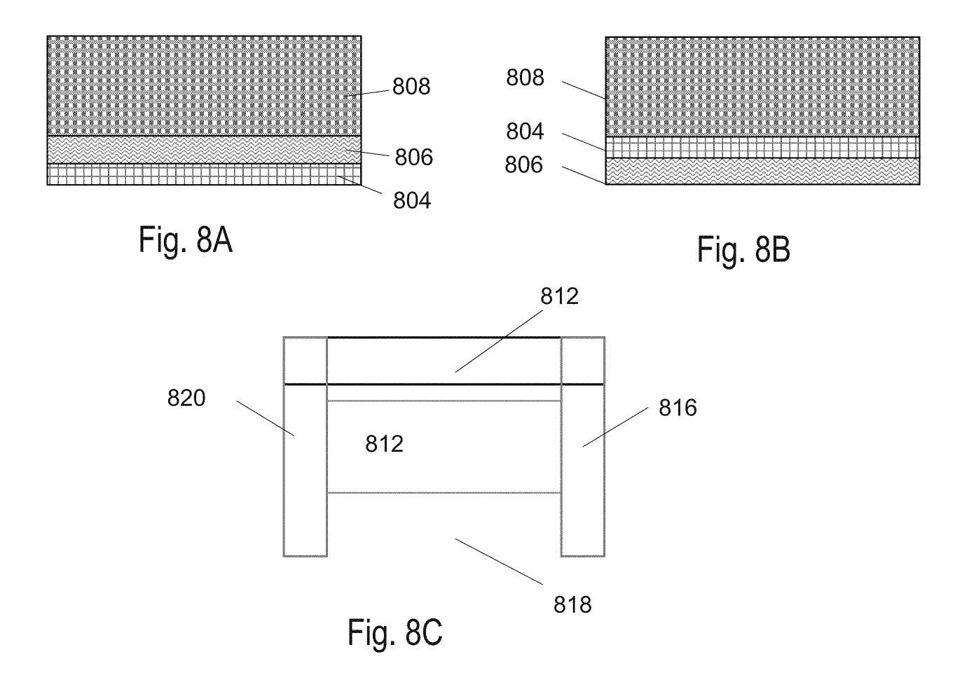

FIG. 8A illustrates a general structure of PDD. Processor layer 804 is overlaid by a 3D-RAM (3D—Random Access Memory) layer 806 providing the processor ‘cache’ memory. A 3D-NAND layer 808 is overlaying the 3D-RAM and is used for a large (tens of Giga-Bits) storage.

FIG. 8B illustrates an alternative PDD structure in which processor layer 804 is disposed in-between 3D-RAM layer 806 and 3D-NAND layer 808.

The 3D NAND layer 808 could be commercially available 3D-NAND or a 3D Nonvolatile memory constructed by one of the available process such as those described in here (or incorporated references). It could utilize non-volatile memory technology such as, for example, charge trap, flash or resistive type memory known as R-RAM. 3D NAND layer 808 may include numerous layers of NAND memory bits and associated circuitry.

The 3D RAM layer 806 could be a fast read write memory as commercially available or as been described in here (or incorporated references) or in U.S. Pat. Nos. 8,379,458 and 8,902,663 incorporated herein by reference. 3D RAM layer 808 may include numerous layers of RAM memory bits and associated circuitry.

Electrical connections between layer within the PDD (not shown), for example, between processor layer 804 and 3D-RAM layer 806 or between processor layer 804 and 3D NAND layer 808 many have a vertical connection density of greater than 10,000 connections/cm², or greater than 50,000 connections/cm², or greater than 100,000 connections/cm², or greater than 300,000 connections/cm², or greater than 500,000 connections/cm², or greater than 1,000,000 connections/cm², or greater than 2,000,000 connections/cm². The connections may be made by Thru Layer Vias (TLVs) which may have diameters of may be about 10 nm, about 20 nm, about 40 nm, about 60 nm, about 80 nm, about 100 nm, about 200 nm, or about 300 nm. The TLVs may be used for thermal connections between the layers, and may be part of a thermal path from the transistors of that layer to an outside surface of the PDD or to the outside surface of a package or coating that the PDD is placed in. A portion of that thermal path may include a contact to a transistor that is thermally conductive but not electrically conductive or a connection elsewhere in the thermal path that has the same function.

FIG. 8C illustrates a block diagram of alternative processor layer 804. The core processor 812 could be single core or multicore, and it communicates with external unit using first communication controller 816 and second communication controller 820. The first communication controller 816 could be used to transfer instructions to the PDD and to transfer data in or out of the PDD. The communication controllers' first communication controller 816 and second communication controller 820 could support networks such as internet or other type of network or busses. Those could be wired, optically connected, or wirelessly connected. 3D-RAM Controller 812 is used to get data in and out of the 3D-RAM layer 806. It could include also the 3D-RAM peripheral circuits such as memory decoders and sense amplifiers. 3D-NAND Controller 818 is used to get data in and out of the 3D-NAND layer 808. It could include also the 3D-NAND peripheral circuits such as memory decoders and sense amplifiers.

The vertical lines (such as including TLVs) connecting the 3D-RAM layer 806 to the processor layer 804 could be as short as tens of nanometers to few micro meters. The vertical lines connecting the 3D-NAND layer 808 to the processor layer 804 could be as short as tens of nanometers to few micro meters.

The processor layer 804 could be made with two similar layers to have one provide redundancy and repair to the other as had been described in at least U.S. Pat. No. 8,669,778 as related to at least FIG. 25 to FIG. 38.

The processor layer 804 could include programmable logic cores or structure such as are known in the art or as is described in at least U.S. Pat. No. 8,669,778 as related to at least FIG. 3A to FIG. 17. It could utilize gate array such as is described in at least U.S. Pat. No. 8,669,778 as related to at least FIG. 20A to FIG. 20D and in U.S. Pat. No. 8,803,206 as related to at least FIG. 42A to FIG. 43B. It could include processor such as those offered by companies such as ARM Holding plc or Imagination Technologies Group plc, those could be RISC or CISC or GPU based and so forth.

The processor layer 804 could include a heat removal path from the processor logic circuits to the external surface of the PDD as is described in at least U.S. Pat. No. 8,803,206 as related to at least FIG. 5 to FIG. 16 and in another parts herein or incorporated by reference documents. A portion of that heat removal path may include a contact to a transistor that is thermally conductive but not electrically conductive or a connection elsewhere in the thermal path that has the same function.

An additional application of the suggested flows herein could be to address the challenge of bottom contacts to the emerging class of vertical nanowire transistors. Vertical Nanowire transistors-“VNWT” are being considered as good candidate for transistors at technology nodes below 7 nm. There are many techniques being presently developed to form such vertical nanowire transistors. Some use epitaxial processes to grow these nanowires and other use etching to form them.

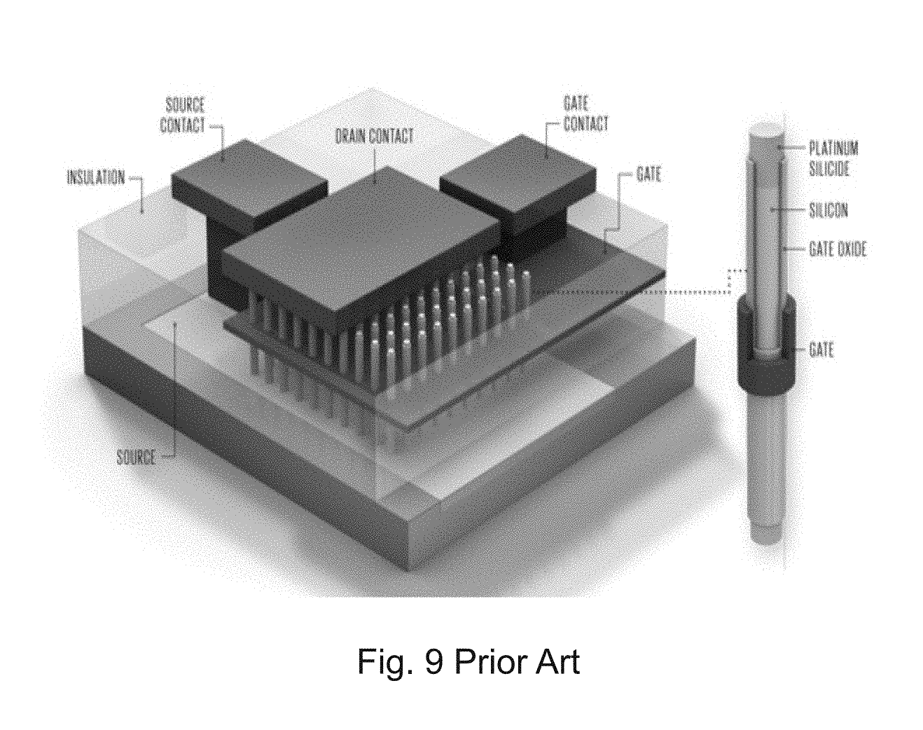

FIG. 9 illustrates a prior art vertical nanowire transistors structure as was published in Spectrum Magazine April 2013 in an article entitled “Nanowire Transistors Could Keep Moore's Law Alive.”

The modified ELTRAN process flow described herein could be used to allow simple access to both sides of the VNWT. The process flow starting point could be a donor wafer substrate as is illustrated in at least FIG. 25 of U.S. patent application Ser. No. 14/642,724, instead of a conventional bulk substrate.

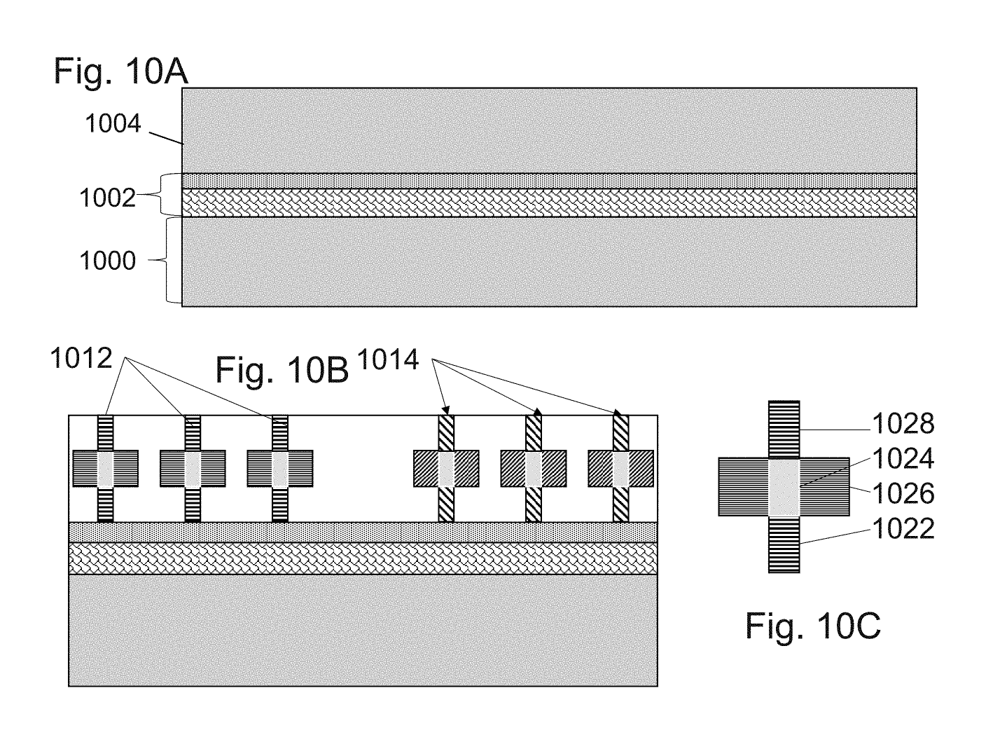

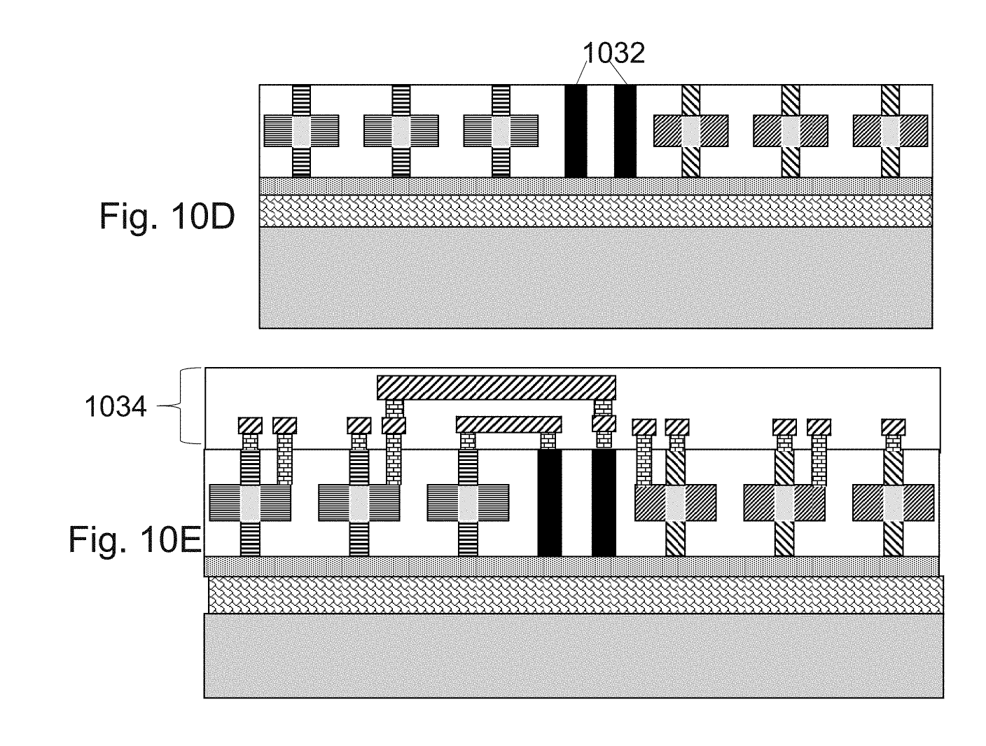

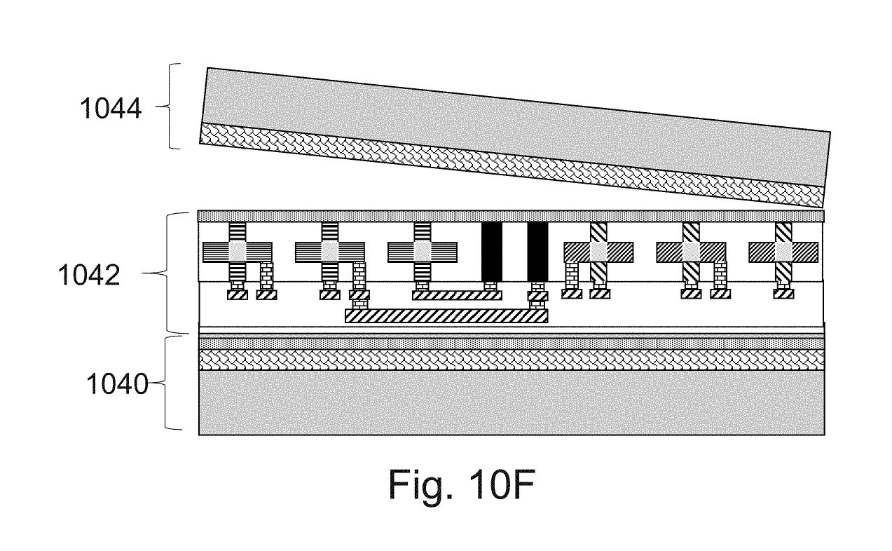

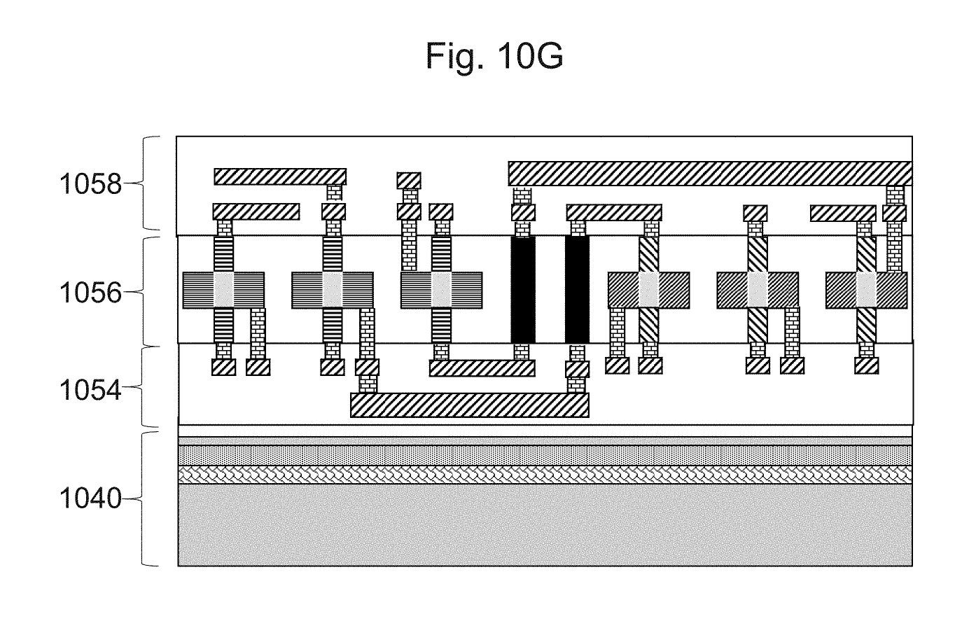

FIG. 10A illustrates a starting donor wafer which is similar to what was described in respect to at least FIG. 25 of U.S. patent application Ser. No. 14/642,724. It includes a bulk substrate 1000, porous dual cut layers 1002, and an epitaxial layer of P doped mono-crystalline silicon.

As illustrated in FIG. 10B, the donor wafer may be processed to form N type VNWT 1012 and P type VNWT 1014. N type VNWT 1012 and P type VNWT 1014 may be constructed over or in epitaxial layer 1004 and may form a transistor layer.

FIG. 10C illustrates some elements of a VNWT, such as drain 1022, channel 1024, all around gate 1026 and source 1028. N type VNWT 1012 and P type VNWT 1014 may include these elements and the elements may be appropriately doped/materials used for the transistor type or function desired.

As illustrated in FIG. 10D, through layer vias “TLV” 1032 may be formed thru the VNWT layer, and may be formed thru the STI or other isolation regions of the VNWT layer, thus avoiding any dielectric liners.

As illustrated in FIG. 10E, source side interconnect 1034 may be formed, and may include conductive interconnect materials such as tungsten, aluminum, copper, CNTs, graphene as dictated by design and process engineering choices, for examples, temperature footprint of follow-on processing may affect material choice.

As illustrated in FIG. 10F, the structure of FIG. 10E may be flipped and bonded to and on top of new carrier wafer 1040. The bulk of the donor wafer 1044 may be cleaved or ‘cut-off’ leaving bonded to the new carrier wafer 1040 the partially connected VNWT layer 1042, with its N type transistors, P type transistors, the TLVs and the source side interconnect 1034 now being down looking.

As illustrated in FIG. 10G, drain side interconnects 1058 to N type VNWT 1012 and P type VNWT 1014 may be formed as well as connection to the TLVs 1032. Thus, a fully connected VNWT transistor layer and device may be constructed and may include source side interconnects 1054, VNWT transistor layer 1056, and drain side interconnects 1058 on new carrier wafer 1040. In one alternative flow, TLVs may be formed at this step, connecting to the source side interconnect 1034, rather than previous to the VNWT layer transfer. New carrier wafer 1040 may include built-in detach layers, for example, dual porous silicon layers, for future integration and layer transfer processing.

The flow presented in respect to FIG. 10A to FIG. 10G for VNWT drain-side connectivity and source side connectivity could be deployed for 3D devices such as by modifying the flow presented in respect to FIG. 1A to FIG. 4C. FIG. 4C is a 3D device having two layer of CMOS transistors with each having connectivity from both sides. So accordingly, a similar flow could be used for VNWT resulting in two layers of VNWT each having connectivity on both the source side and the drain side.

In forming a logic device using VNWT it would be more effective to use a logic cell library designed to have all inputs and outputs from the side such as the source side, using the other side for inter-cell connectivity, and high (‘Vdd’) and low (‘Vss’) connection.

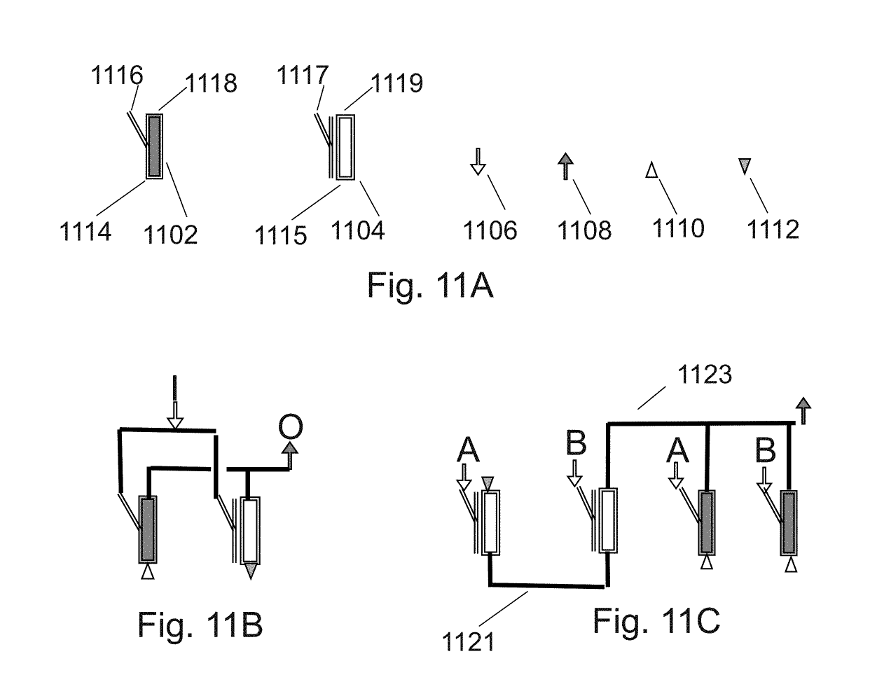

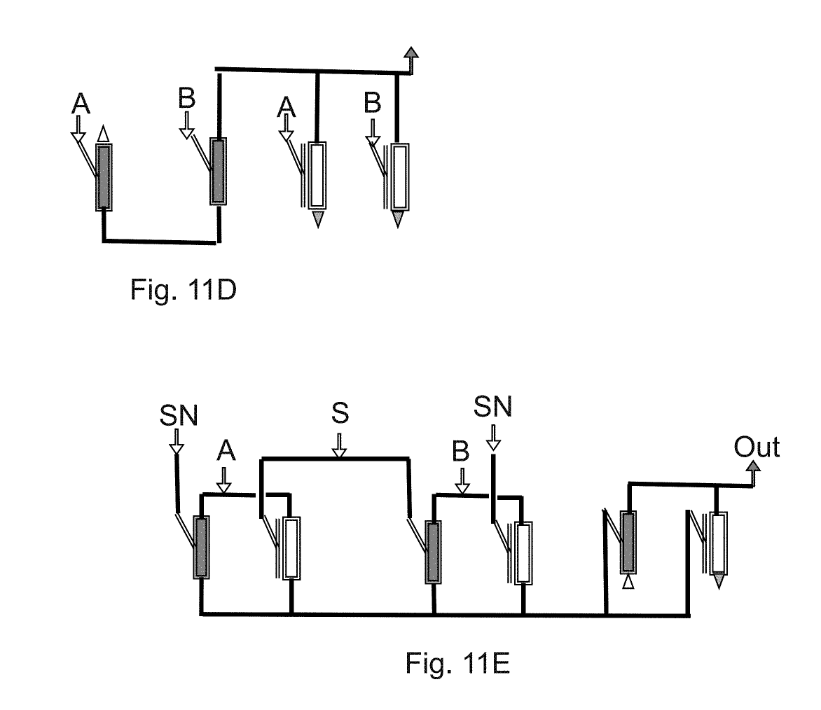

FIG. 11A is illustrating elements/symbols which will be utilized in the following drawings, at least FIGS. 11B to 11E, to illustrate some cell library exemplary constructions for VNWT type logic. An N type transistor 1102 may include drain side connection 1114, source side connection 1118 and gate connection 1116. A P type transistor 1104 may include drain side connection 1115, source side connection 1119 and gate connection 1117. Other elements are an input 1106, an output 1108, a logic low 1110 and a logic high 1112.

FIG. 11B illustrates an Inverter logic cell using the above elements and black lines illustrating source side interconnects to invert input I to output O.

FIG. 11C illustrates a NOR logic cell using the above elements and black lines illustrating source side interconnects 1123, and drain side interconnects 1121 to perform a NOR operation on inputs A, B.

FIG. 11D illustrates a NAND logic cell using the above elements and black lines illustrating source side interconnects, and drain side interconnects to perform NAND operation on inputs A, B.

FIG. 11E illustrates an inverting selector to select between input A or B and to output which will be the inverted selected input, signal S and its inversion SN will determine which input is selected.

In a similar manner a full macro-cell logic library could be constructed. In general these macro-cells are part of the known in the art building blocks for enabling logic designs using standard industry EDA (Electronic Design Automation) tools. A macro-cell library usually includes the functionality information such as the logic function and its timing, and the physical information such as size and the full layout data for each cell including the shape in the relevant layer such as the transistor layers and the first layer of interconnects such as metal 1 and metal 2 and in some case even metal 3 (mostly for SRAM cells).

The functionality data could be used for the front part of the design effort such as synthesis simulation verification and testability preparation. The physical data could be used for the physical design part such as Place and Route and DRC and LVS checking phase.

In the common macro-cell library physical data the transistor connectivity forming the cell in the macro-cell library is all upper layer interconnection layers such as metal 1 and metal 2. In a 3D device such as, for example, the one illustrated herein, the macro cell library could include metal used macro-cell interaction both above and below the transistors has been illustrated in FIG. 11C-FIG. 11E.

In the common macro-cell library physical data the transistor connectivity forming the cell in the macro-cell library is all upper layer interconnection layers such as metal 1 and Metal 2. And these macro-cell are then interconnected to form the logic circuit utilizing the upper interconnection layer such as metal 3 and metal 4 and many times many additional overlaying metal layers. In a 3D device such as, for example, the one illustrated herein, the interconnection layers could be added on the other side as is illustrated in FIG. 3D. In FIG. 3D some of the macro-cell internal transistor connection could use the metal layers underneath local interconnection 155 and optional shielding 157 while the interconnection between the macro-cell could be illustrated by the metal layers on the other side interconnect layers 308. In general the macro-cell internal connection are defined in the macro-cell library and will be determined for a specific device at the EDA Placement step while the connection between cell will be designed at the EDA Routing step. Once everything had been verified and no more modifications are required the EDA tool will output the mask data for the following step of processing the device using masks produced accordingly.

In U.S. Pat. No. 8,237,228, incorporated herein by reference, some macro-cell implementations for 3D device have been illustrated. For example, in at least FIG. 64G of U.S. Pat. No. 8,237,228 a macro-cell is illustrated constructed with two transistor layers of which one is utilizing vertical (PNP) transistors overlaying horizontal N type transistors. With 3D devices constructed similar to what have been presented herein, multiple options are available to construct devices to fit specific needs using horizontal and/or vertical transistors constructing these cell libraries on one or more layer of transistors and using inter-cell connections overlaying cell transistors and/or using inter-cell connections underlying cell transistors as has been illustrated.

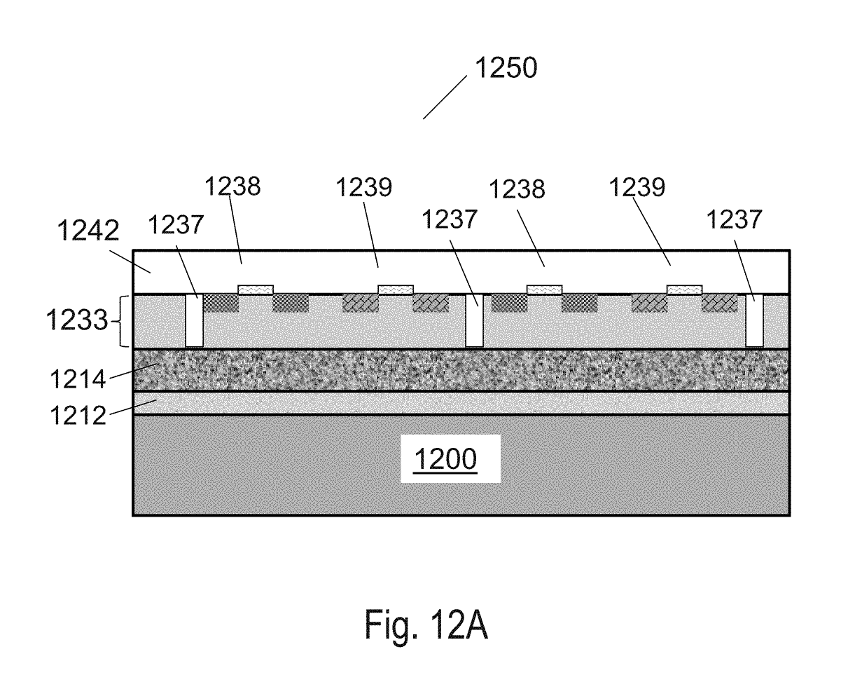

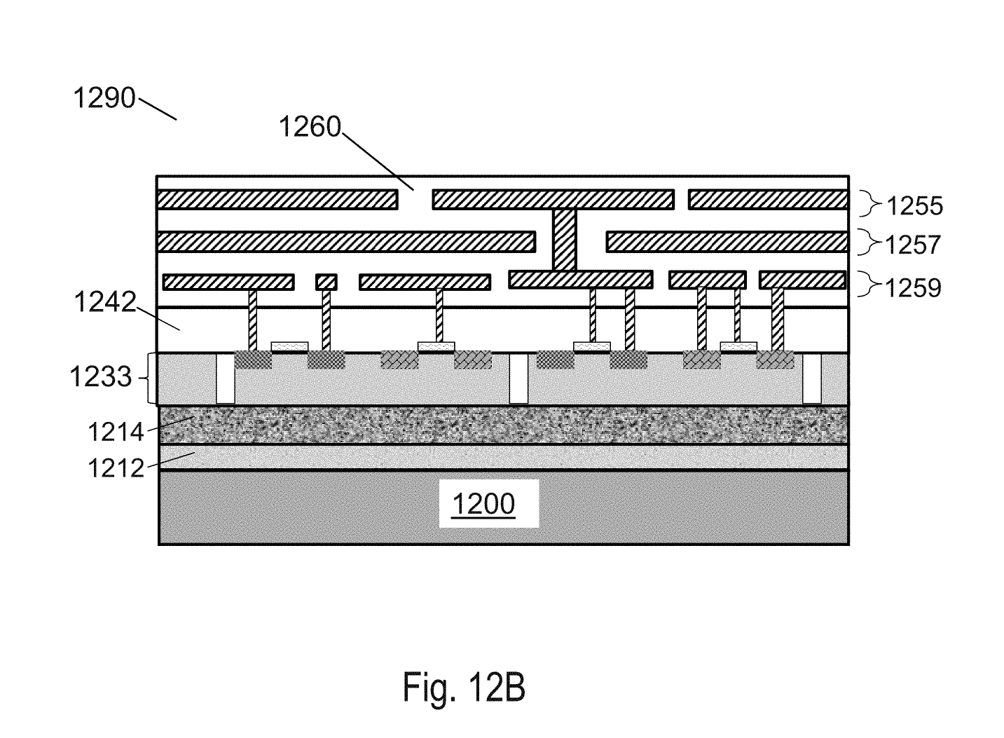

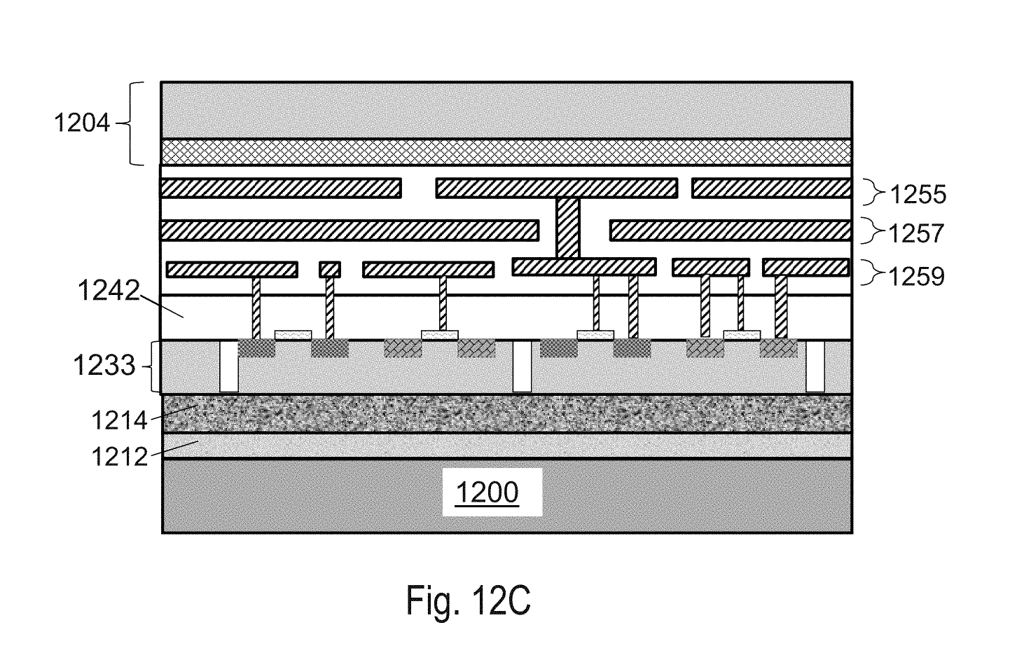

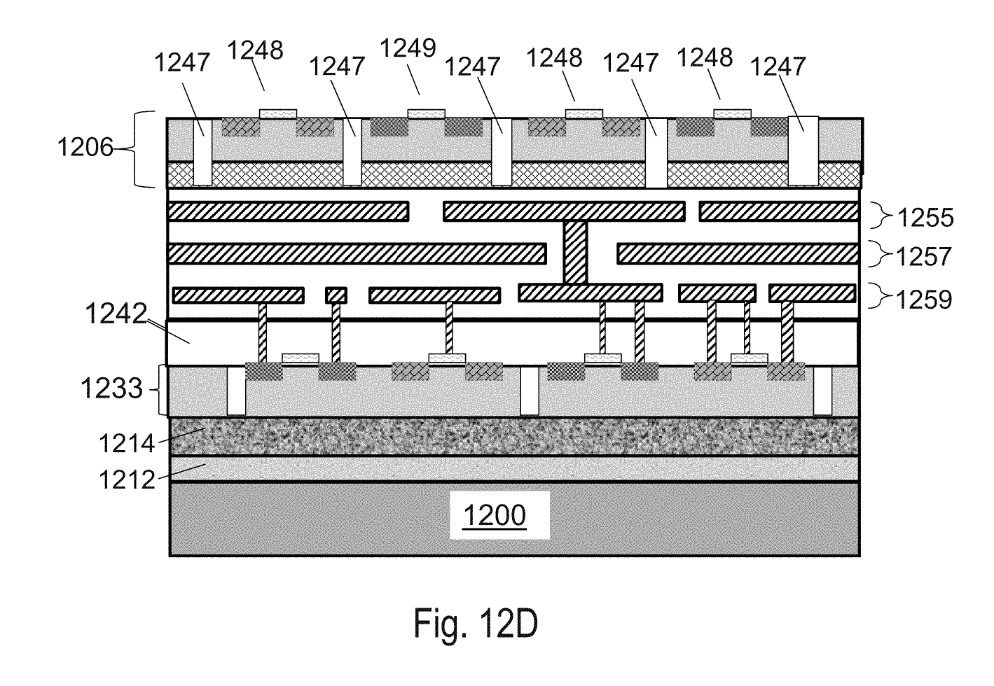

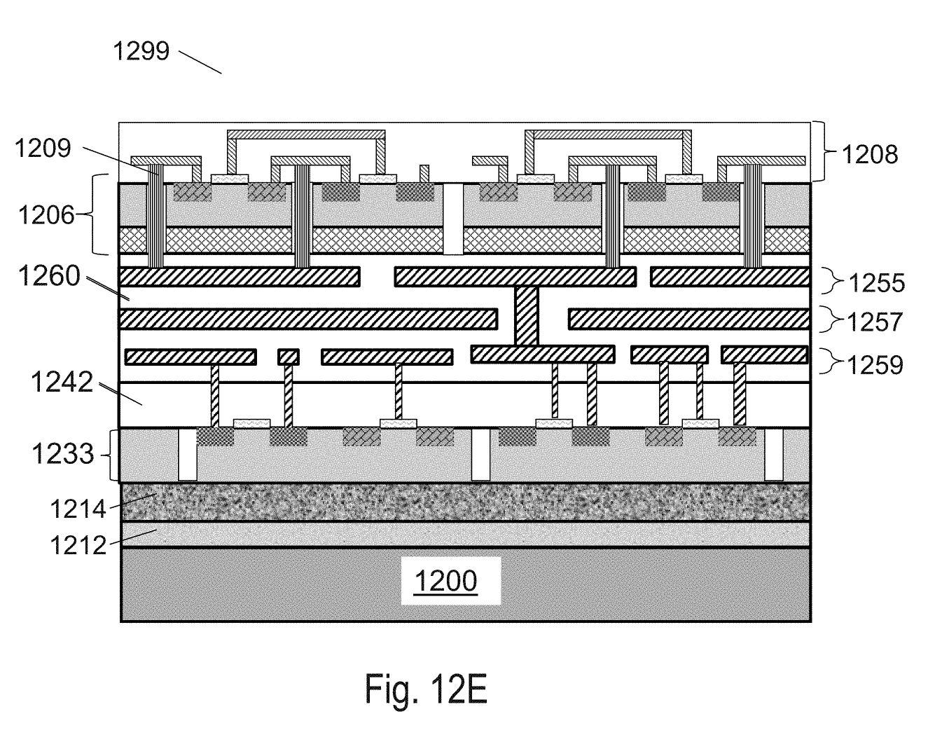

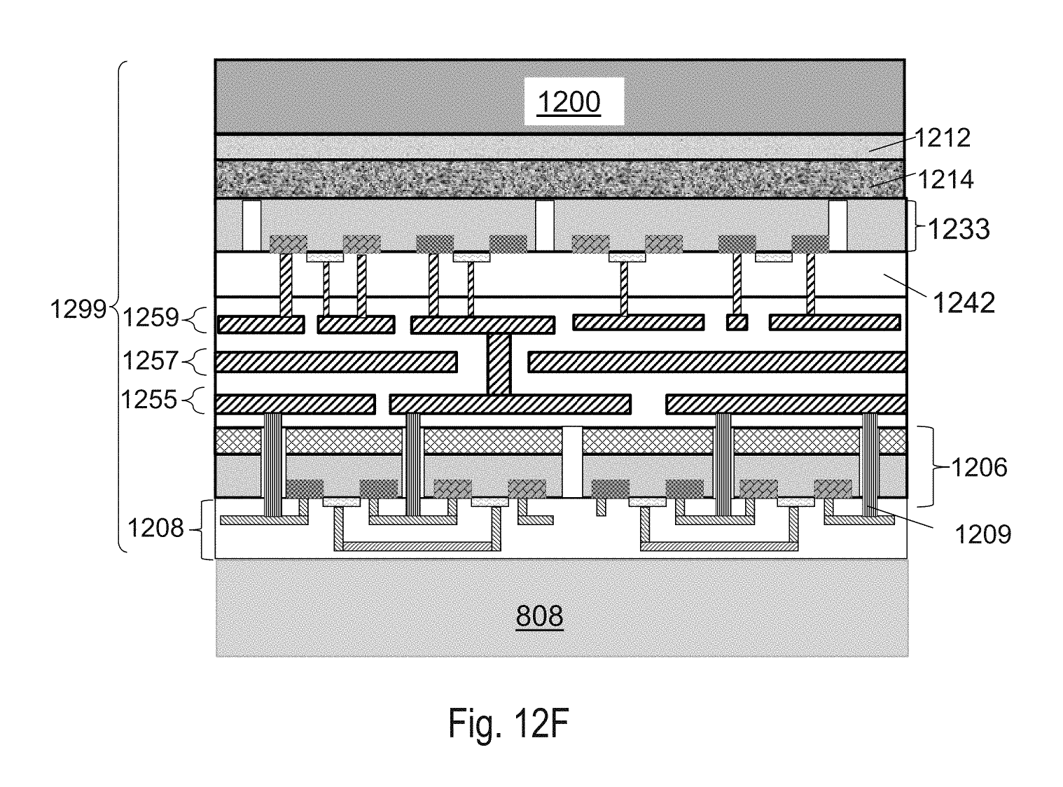

As illustrated in FIG. 12A, a Stratum-3 layer transfer structure 1250 may be constructed and may be formed utilizing methods similar to FIGS. 1A-1D herein. Stratum-3 layer transfer structure 1250 may include substrate 1200, lower porous layer 1212, upper porous layer 1214, Stratum-3 device layer 1233, and dielectric 1242. Lower porous layer 1212, upper porous layer 1214 may be formed by means of anodization on a substrate 1200 such as a silicon wafer. The upper layer of porous silicon upper porous layer 1214 contains microscopic pores of diameter a few nm, and below this is formed lower porous layer 1212 for which the pore diameter is a few times greater than the upper porous layer 1214. In some applications it might be desirable to use the modified ELTRAN process for the fabrication of a 3D device with multiple layers of crystals. The flow herein utilizes a donor wafer similar to donor wafer 110 herein, but other types of donor wafers may be utilized due to various engineering choices. Stratum-3 device layer 1233 maybe formed with conventional front line processing of an epi layer (or an ion-cut monocrystalline layer, for example silicon) to construct at least N type transistors 1238 and P type transistors 1239 and shallow trench isolations—STI 1237, in between the transistors. Other devices (not shown), such as diodes, capacitors, resistors, may be constructed/formed as well). These devices and structures may be processed and formed with conventional semiconductor processing. Thus the devices of Stratum-3 1233 may be formed. At the point all the elements on the transistor side of Stratum-3 1233 which needs high temperature (>400 C) for their formation could be processed, for example, such as gate oxidation, dopant activation, and silicidation for transistor contacts and LDD. Dielectric 1242 may include one or many materials and layers, for example, silicon oxides, porous silicon oxides, doped or undoped and/or carbon doped silicon oxides. Stratum-3 layer transfer structure 1250 may utilize the donor wafer style of improved carrier wafer 165 herein.

As illustrated in FIG. 12B, front-side interconnections of stratum-3 devices may be processed and formed on top of and/or partially within dielectric 1242. These interconnection layers could use refractory metals such as tungsten so that they could withstand following steps of high temperatures (>400 C). These interconnections could include, for example, local connections for Stratum-3 1259, power distribution or optional shielding 1257, and local backside interconnection 1255 for future Stratum-2. Inter-metal dielectric 1260 may include low k dielectrics and conventional silicon oxide depending on future temperature exposure process integration choices. Thus Stratum-3 processed structure 1290 may be formed. Stratum-3 processed structure 1290 may include local connections for Stratum-3 1259, power distribution or optional shielding 1257, local backside interconnection 1255, inter-metal dielectric 1260, dielectric 1242, Stratum-3 device layer 1233, upper porous layer 1214, lower porous layer 1212, and substrate 1200.

As illustrated in FIG. 12C, a stratum-2 layer transfer structure (for example, such as stratum-2 layer transfer structure 202 described herein) may be flipped and bonded on top of the Stratum-3 processed structure 1290, thus forming S2 layer 1204. Bonding and isolation oxide layers may be utilized for the bonding (not shown). S2 layer 1204 may include a substantial portion or substantially all of, for example, the S2 epitaxial layer 220, and may include S2 backside layer 222. Other layer transfer techniques such as ion-cut could alternatively be used to form S2 layer 1204 as the use of higher than 400° C. is acceptable.

Alternatively the donor wafer, for example a stratum-2 layer transfer structure 202, could be processed for ion-cut layer transfer technology rather than with a ‘Modified ELTRAN’ technology. In such case instead of the porous layers and epitaxial deposition, an implant of H+ or other ion or combination of ions (described in detail in at least incorporated reference U.S. Pat. No. 8,273,610) could be used to form a cut layer of ion damage in replacement of the porous cut layers upper porous layer 214, lower porous layer 212. An advantage of combining two types of ‘cut’ layers—porous and ion—is the ease in selecting which layer would get cut at which point of the process flow. For example, in the case of the structure of FIG. 2A, the cut of the donor wafer stratum-2 layer transfer structure 202 would be done by heating the entire structure to a temperature between 500° C.-800° C., thereby splitting at or near the ion-cut damage layer but not affecting porous layers of the underneath donor wafer improved carrier wafer 165. Since the structure of FIG. 12A does not include copper or aluminum interconnection layers such an alternative could be easily adapted. Furthermore, improved carrier wafer 165 may not require the extra processing to ‘improve’ it, sidewalls 168.

As illustrated in FIG. 12D, S2 layer 1204 may go through front line processing to construct at least S2 N type transistors 1248 and S2 P type transistors 1249 and S2 shallow trench isolations—STI 1247, in between the transistors, thus forming Stratum-2 1206. Other devices (not shown), such as diodes, capacitors, resistors, may be constructed/formed as well). These devices and structures may be processed and formed with conventional semiconductor processing. Thus the devices of Stratum-2 1206 may be formed. At the point all the elements on the transistor side of Stratum-2 1206 which needs high temperature (>400 C) for their formation could be processed, for example, such as gate oxidation, dopant activation, and silicidation for transistors contacts and LDD. Stratum-2 structures could be aligned to the interconnection underneath and/or Stratum-3 using lithography alignment marks as these layers are thin enough for the stepper/aligner to see thru at short wavelength light, thus allowing state of the art alignment; for example, alignment of Stratum-2 and Stratum-3 devices and structures to less than about 2 nm, to less than about 4 nm, to less than about 8 nm, to less than about 10 nm. In some cases there might be concern in respect to the effect on the thermal budget of Stratum-3 from the high temperature process associated with forming Stratum-2. Using lasers, for example excimer lasers, for the Stratum-2 high temperature steps and proper shielding such as optional shielding 1257 could help to reduce the negative impact on Stratum-3 transistors. Variations of processing techniques to allow high temperatures processing of Stratum-2 while reducing the effect on the underling structure such as Stratum-3, for example, using such shielding layer were presented in more detail in at least U.S. Pat. Nos. 9,023,688 and 8,574,929, incorporated herein by reference.

As illustrated in FIG. 12E, stratum-2 through layer vias 1209 and S2 interconnect layers 1208 may be formed. Copper or aluminum could be used to provide the conductive interconnection. Stratum-2 through layer vias 1209 may pass thru Stratum-2 1206 and electrically and thermally couple devices in Stratum-2 1206 (for example S2 N type transistors 1248 and S2 P type transistors 1249) to local backside interconnection 1255. Later in the processing, stratum-2 through layer vias 1209 may enable electrical and/or thermal coupling of devices on Stratum-2 1206 (for example S2 N type transistors 1248 and S2 P type transistors 1249) to devices of Stratum-3 1233 (for example N type transistors 1238 and P type transistors 1239), which may be considered thermally conductive paths and/or electrically conductive paths. Thus dual strata donor structure 1299 is formed. Dual strata donor structure 1299 may include S2 interconnect layers 1208, local connections for Stratum-3 1259, stratum-2 through layer vias 1209, Stratum-2 1206, power distribution or optional shielding 1257, local backside interconnection 1255, inter-metal dielectric 1260, local connections for Stratum-3 1259, dielectric 1242, Stratum-3 device layer 1233, upper porous layer 1214, lower porous layer 1212, and substrate 1200.

As illustrated in FIG. 12F, dual strata donor structure 1299 may be flipped and bonded on top of a target carrier or wafer 808. Description of target wafer/substrate 808 may be found in at least referenced U.S. Pat. No. 8,273,610. Bonding and isolation oxide layers may be utilized for the bonding (not shown).

As illustrated in FIG. 12G, the bulk substrate of dual strata donor structure 1299 may be split off leveraging lower porous layer 1212 and upper porous layer 1214. Substrate 1200 may be recycled for further use. Cleaning of the porous residues and smoothing of the backside of Stratum-3 device layer 1233 may be performed. Connection layer 1216 may be formed. Connection layer 1216 may include S3 through layer vias 1218 for connecting Stratum-3 to the local connections for Stratum-3 1259, Stratum-3 interconnects 1211, pads 1214 for connection to other devices and the pad to S3 interconnects 1212 for connection of these pads 1214 to Stratum-3 interconnects 1211. Dual strata structure 1206 devices may be electrically and/or thermally connected to the devices and structures of target wafer/substrate 808 (not shown), as described in the incorporated references. Dual strata structure 1296 may include two layers/regions of transistors facing downwards.

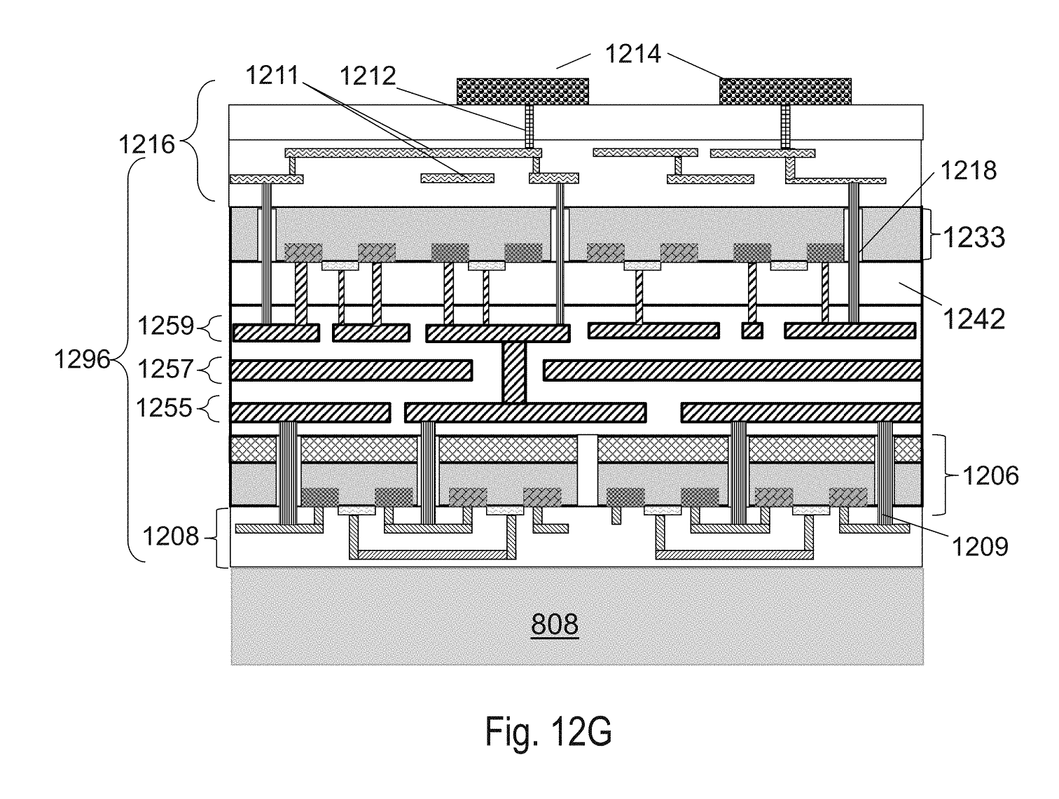

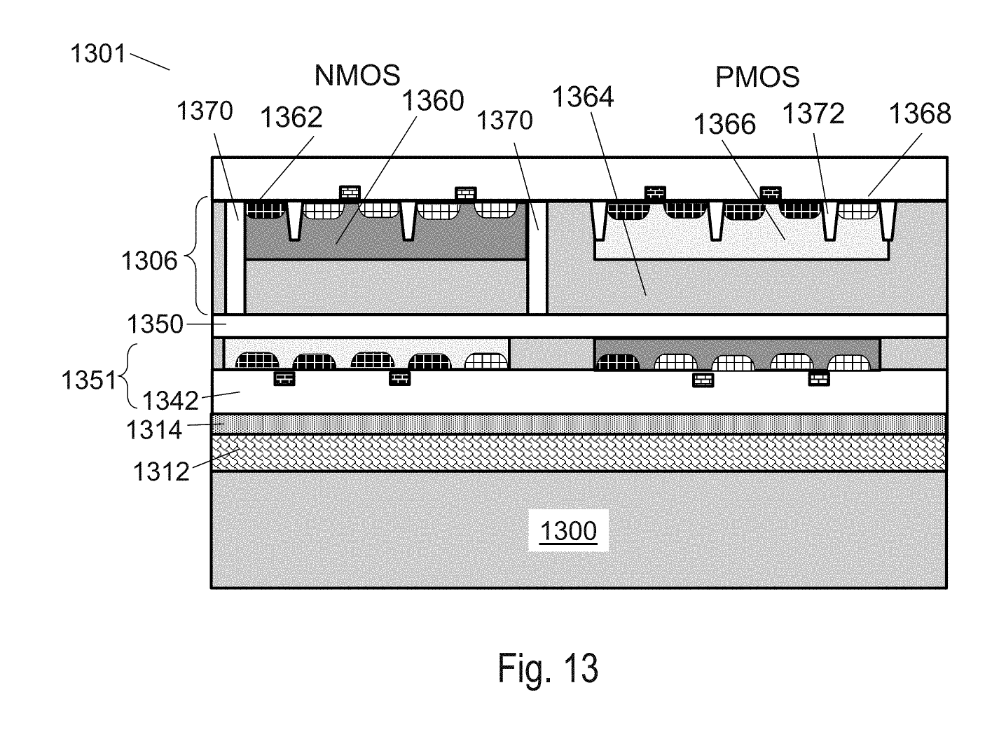

In conventional triple-well CMOS processes, a deep n-well is used as a shielding frame against disturbances from the substrate to provide better insulation from digital noise, suppress latch-up and snapback. Deep n-well processing adds fabrication cost and increases chip area. As illustrated in FIG. 13, a P-well guard ring insulator 1370, for example, (similar to a deep trench isolation, or an extended STI) a ring shaped insulator wall, may be formed to completely isolate between P-well 1360 and N-well 1366. The bottom of P-well guard ring insulator 1370 contacts the vertical isolation 1350 (inter-stratum isolation layer in the case of a dual stratum structure). No need for a triple well process. This guard ring may also be formed by TLV processing. This isolation structure offers better noise immunity, and is latch-up free and snap-back free. This structure may be utilized for single and dual stratum transistor structures such as has been presented herein and in at least the incorporated references. The processing structure 1301 (the structure illustrated in FIG. 13) may include substrate 1300 (which may be similar to substrate 100 herein), lower porous layer 1312 (which may be similar to lower porous layer 112 herein), upper porous layer 1314 (which may be similar to upper porous layer 114 herein), dielectric 1342 (which may be similar to dielectric 142 herein), Stratum-3 1351 (which may be similar to Stratum-3 151 herein, vertical isolation 1350 (which may be similar to local connections for Stratum-3 159, power distribution on optional shielding 157, local interconnection 155, Inter-metal dielectric 160 herein, or may be other isolation schemes-for example substantially all oxide-such as taught in at least the incorporated references), Stratum-2 1306 1342 (which may be similar to Stratum-2 306 herein), P-well guard ring insulator 1370, P-well tap 1362, P-well 1360, P-type epi layer 1364, N-well 1366, STI 1372, and N-Well tap 1368. Continued processing, for example, such as taught or suggested herein, of processing structure 1301 may result in a 3DIC device that includes one or more P-well guard ring insulator 1370 structures. Guard ring insulators may be used around the N-well.

In respect to the modified ELTRAN process to support layer transfer there are alternatives to the step of epitaxial deposition of the silicon layer 120 over what used to be porous layer 113. In one alternative the substrate may be prepared for a specific use in which the silicon area to be used for transistors could be designated.

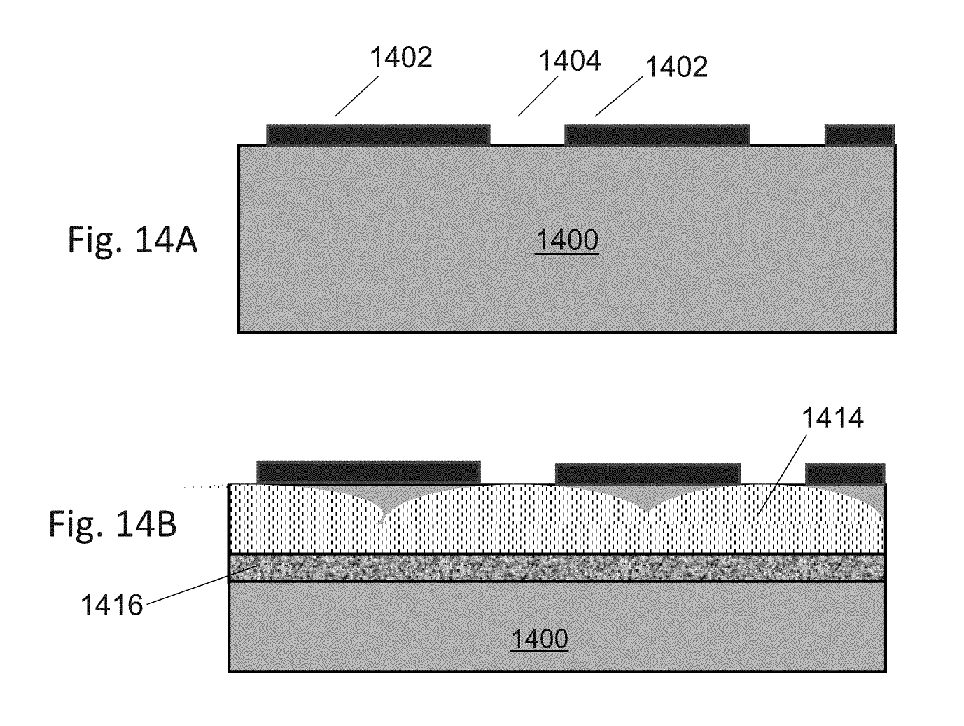

FIG. 14A illustrates a specific substrate with protection areas or transistor designated regions. Accordingly the top layer of the silicon substrate 1400 is patterned covering future transistor/device area 1402 and exposing non-transistor/device regions 1404 such as future shallow trench isolation (“STI”) regions. The future transistor/device area 1402 could be covered by a protective hard mask such as silicon nitride. Alternatively, the top layer of the silicon substrate 1400 may be patterned exposing/opening future transistor/device area 1402 and covering non-transistor/device regions 1404 such as future shallow trench isolation (“STI”) regions, wherein exposed/open future transistor/device area 1402 may be doped n type such that future anodization is limited in that region/area. The substrate may then be placed into an anodizing process forming pores starting in the unprotected/un n-type doped areas and expanding underneath the protected areas.

FIG. 14B illustrates the substrate of FIG. 14A after an anodizing step. The closer to the surface region first porous region 1414 could be anodized to have a relatively lower porosity and underneath it the second porous region 1416 could have a high porosity. Then as previously described herein the wafer/substrate could be cleaned and the porous layer could be hardened by an oxidation to seal the top surface and it could be planarized by a high temperature H₂ annealing. An epitaxial silicon step could be done to further improve the substrate top surface. Note, FIG. 14B illustrates the anodization prices and pore formation presuming the etch proceeded solely along electric field lines (gradient of electrostatic potential).

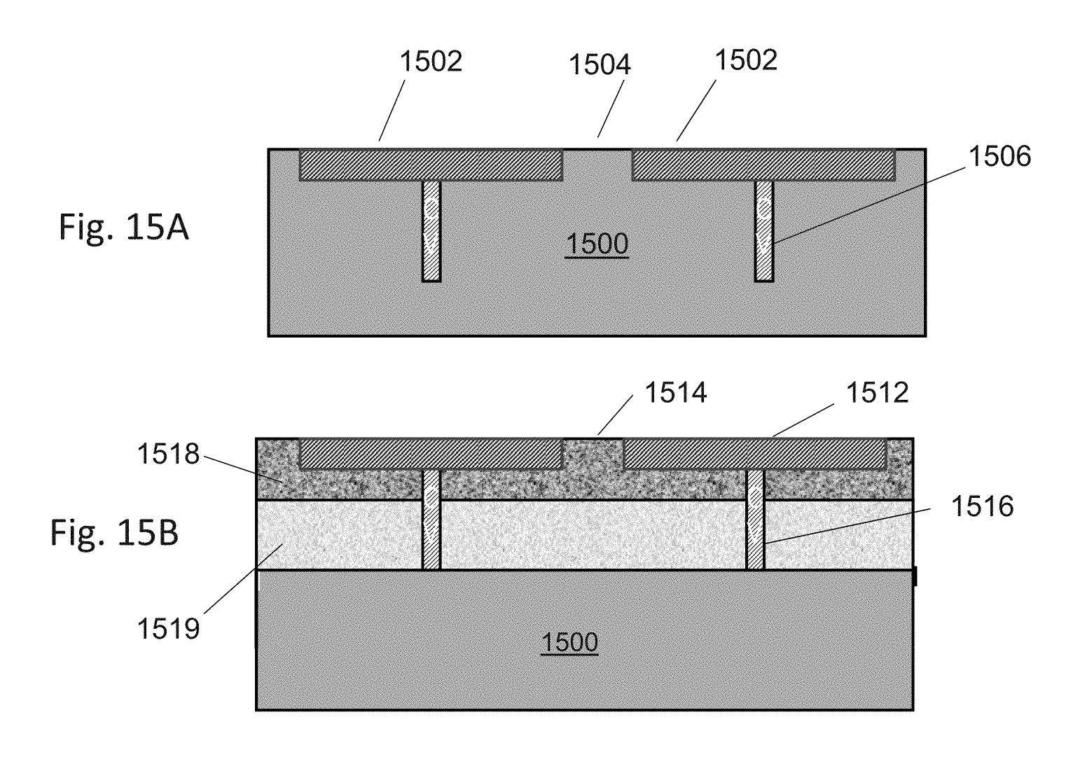

FIG. 15A illustrates another substrate with protected areas or transistor designated regions. Accordingly the top layer of the silicon substrate 1500 could be patterned designating future transistor/device area 1502 and openings thru which to etch through to exposed regions 1504 which could be used later for shallow trench isolation (“STI”) regions. The protected area future transistor/device 1502 could be doped by n type doping or other forms of protection against the forthcoming anodizing etch process. In addition conductive posts 1506 may be placed under the protected regions 1502. These posts could be also N+ type doped, P+ type doped or metallic. The substrate is then put into an anodizing process forming porous regions in the unprotected areas and expanding underneath the protected areas.

FIG. 15B illustrates the substrates following an anodizing step. The porous process could form two levels of porosity, first porous regions 1518 and second porous regions 1519 to support the future layer transfer process. The conductive post 1516 could help the expansion of the porous process under the protected regions 1512. These could allow larger protection regions while still allow for good porous layer/region formation. These could allow a higher ratio for the protected regions 1512 vs. the open regions 1514. Then as before the wafer could be cleaned, the porous layer could be hardened by an oxidation, the top surface could be sealed, and planarized by high temperature H₂ annealing. In such structure the protected regions 1512 could now be used to build transistors on. Alternatively an epitaxial process could be applied to further improve the substrate top surface. Thus, high performance transistors and/or devices could be built on/in protected regions 1512 and could utilize the first porous regions 1518 and second porous regions 1519 for a future layer transfer.

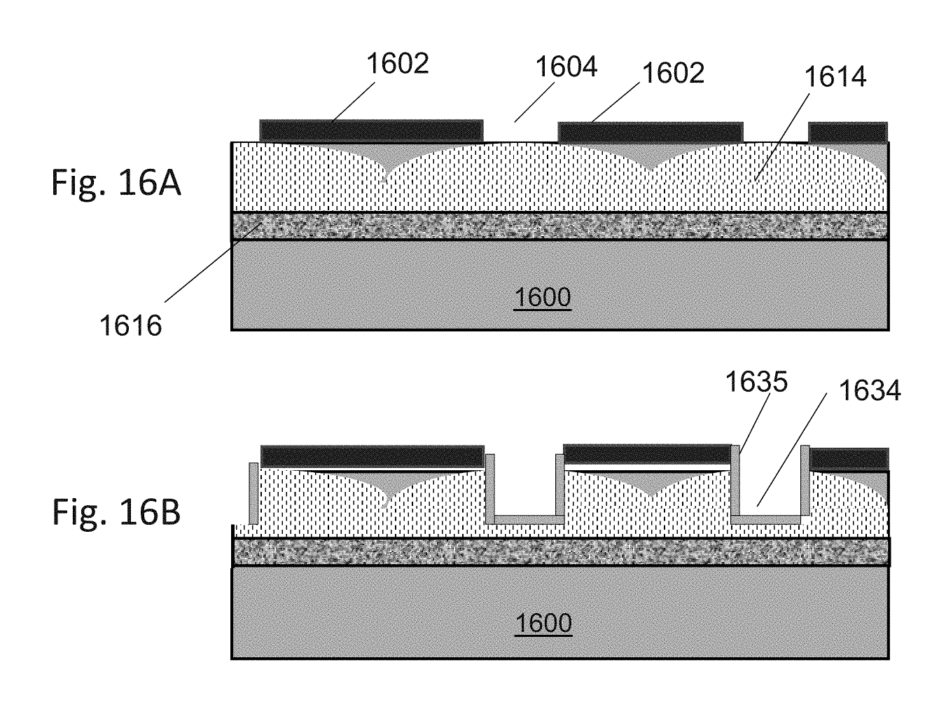

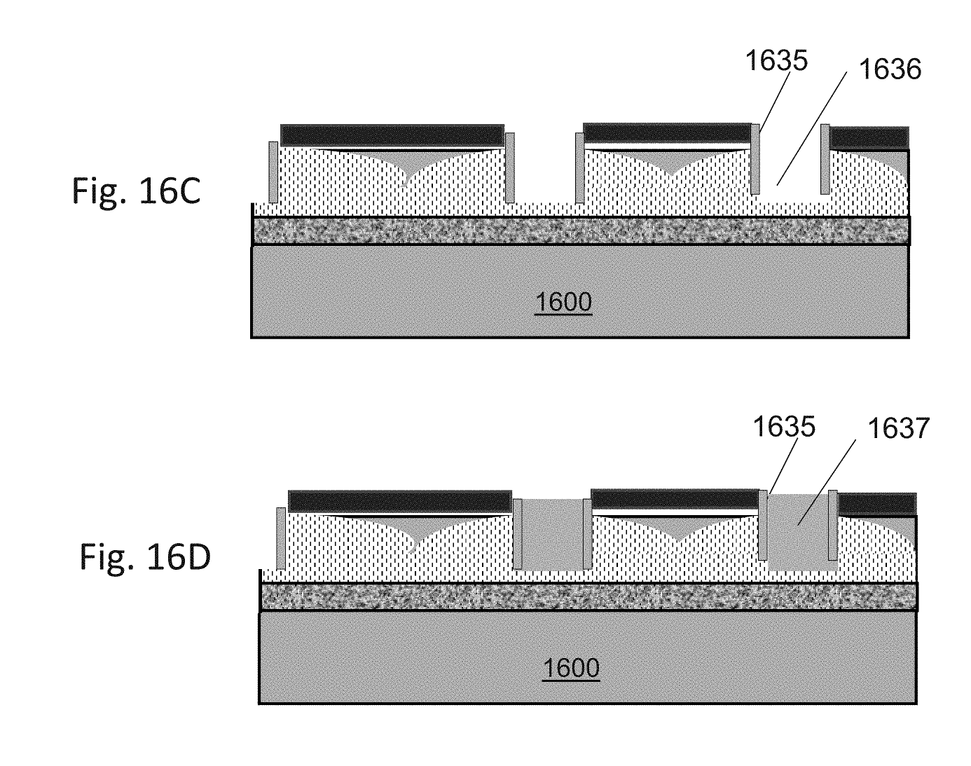

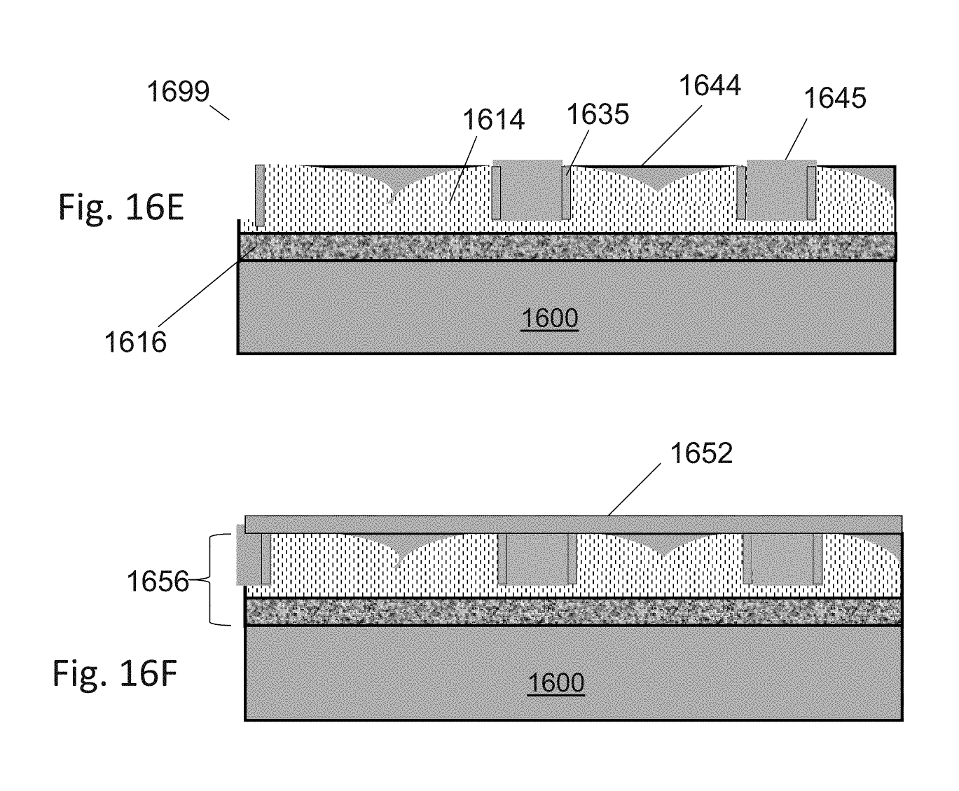

FIG. 16A illustrates a similar structure to FIG. 14B, a specific substrate, with protection areas or transistor designated regions, which has been treated with anodization processing. This structure may include silicon substrate 1600, which may be patterned covering future transistor/device area 1602 and exposing non-transistor/device regions thru opening 1604, first porous region 1614 (which could be anodized to have a relatively lower porosity) and underneath it the second porous region 1616. Such structures could be further processed to enhance the quality of the eventual silicon layers in portions of the regions of first porous region 1614 designated before as non-transistor/device regions 1404/1414, for example as regions for STI.

FIG. 16B illustrates the structure of FIG. 16A after etching into first porous layer 1614 through the openings 1604 and then followed with deposition of a thin protection layer, such as, for example, wall silicon oxide 1635 substantially covering the walls and the bottom silicon oxide 1634 substantially covering the bottom of the etched holes/regions.

FIG. 16C illustrates the structure of FIG. 16B after a directional etching, for example, such as RIE, thus opening the bottoms 1636 of these holes.

FIG. 16D illustrates the structure of FIG. 16C after processing to provide monocrystalline regions 1637. The top exposed portion of first porous region 1614 may be sealed by using high temp hydrogen annealing with added silicon as was described previously. Then selective epitaxial of silicon may be utilized to fill these holes, thus providing monocrystalline regions 1637. This technique, when utilized with the proper aspect ratio of the holes, forms a defect free top surface as all defects related to dislocation and other issues will propagate to the walls (towards wall silicon oxide 1635) in about 45 degrees growth pattern. This well-known technique has been described before herein and in the at least the incorporated references.

FIG. 16E illustrates the structure of FIG. 16D after removing the oxide and other protection material and planarizing the top surface, utilizing, for example, high temperature H₂ annealing and/or CMP techniques. Thus, planarized monocrystalline regions 1645 may be formed and the originally protected silicon regions may be exposed. The top surface now includes the original protected silicon regions 1644 and the defect free epitaxial grown planarized monocrystalline regions 1645. Multi monocrystalline region dual porous layer substrate 1699 may include substrate 1600, first porous region 1614, second porous region 1616, wall silicon oxide 1635, original protected silicon regions 1644 and planarized monocrystalline regions 1645.

FIG. 16F illustrates the structure of FIG. 16E after an optional additional epitaxial step forming high quality top surface 1652 over dual porous structure 1656 to support future ‘cut’ for layer transfer.

It might be desired to use alternative device/wafer layout and dicing techniques to increase the effective yield of a 3DIC process flow. An embodiment of an invention is to utilize die to wafer assembly techniques for 3D IC stacking to break-off from a larger desired die sub-die that have tested good, and only utilize the good sub-die to be subsequently placed in the 3DIC stack (which may for the larger desired die size for that stack layer), thereby increasing the overall yield of 3DIC stack systems/devices. The ability to perform this accurately and precisely may require, for example, a high precision die to wafer placement capability as has been presented in U.S. patent application Ser. No. 14/642,724 as well as the three phase die to wafer bonding scheme U.S. patent application Ser. No. 16/149,651, the foregoing applications are incorporated herein by reference. This could be particularly effective when utilized with the continuous array concepts, layout, designs, and flows as has been presented in at least the complete list of incorporated references herein.

Another application in which 3D devices could be very effective are injectable/implantable electronics. In some applications it could be very effective to have a fully functional device at a tiny size, such as less than about half mm for each side (x, y, z). A 3D device such as one utilizing some of the processes previously described could allow integration of many functions while still keeping each of the device side to be less than 0.5 mm or similar small size that could fit such applications as injectable or implantable using micro-surgery, endoscopy, and similar minimal invasive procedures.

The functionality of such micro-3D device could include:

1) Energy source such as: micro battery or super-capacitor. A porous layer could be very useful for such a function.

2) An energy harvesting circuit. An electro-magnetic device could be designed to harvest selected electromagnetic waves in similar fashion to what is now becoming popular for wireless charging of cell phones. Such energy harvesting techniques are presented in at least US patent applications, such as U.S. Pat. No. 9,029,173, Ser. Nos. 13/716,376, 13/859,329, and 14/060,622, incorporated herein by reference.

Alternatively energy harvesting circuit could use an ultrasound tuner to harvest ultrasound waves to charge the internal power storage element. Such energy harvesting techniques are presented in at least US patents applications such as U.S. Ser. Nos. 10/043,129, 10/465,431, 13/421,476, 13/421,500, and 13/671,486, incorporated herein by reference.

3) Device controller. The device controller could include an 8 bit microcomputer such as 8051 or 16 bit ARM architecture based or other type of microcomputer computer. In some applications it could be desired to operate at subthreshold to consume minimal power.

4) Sensor unit. The senor unit could be an image sensor, chemical sensor, or electromagnetic sensor, or other type of sensing element.

5) A wireless radio such as blue-tooth or utilizing other communication protocol to transmit and receive data and instructions.

It could be desired to have each of these functions in its own layer or stratum of the 3DIC microsystem, which may be processed using the appropriate process (such as type, max Vcc, node, etc.) for that function by leveraging the techniques previously presented to build a 3D microsystem.

In some applications it might be desired to control the location of the 3D microsystem within the body. Magnetic force could be used to position and reposition the 3D microsystem. These forces could be applied from an external source. To have the 3D microsystem respond to magnetic force a magnetic structure could be integrated within the 3D microsystem or on its outer surface. A ferromagnetic material could be used and then magnetized before being injected or inserted into the body.

In such micro-3D system, it might be desired to use alternative dicing techniques to allow far narrower than conventional streets/dicelines to reduce the overall wafer area allocated to the dicing streets. Use of laser and water jet dicing could allow less than 100 micron wide streets. Another approach would be etching techniques and plasma assisting etch and combination of laser and plasma etch to reduce the dicing streets to less than 50 micron wide streets or even less than 20 micron wide streets. Such dicing techniques are presented in at least US patents applications such as U.S. Ser. Nos. 12/549,825, 13/160,713, 13/168,020, and 13/938,537, incorporated herein by reference

Some embodiments of the invention may include alternative techniques to build IC (Integrated Circuit) devices including techniques and methods to construct 3D IC systems. Some embodiments of the invention may enable device solutions with far less power consumption than prior art. The device solutions could be very useful for the growing application of mobile electronic devices and mobile systems such as, for example, mobile phones, smart phone, and cameras, those mobile systems may also connect to the internet. For example, incorporating the 3D IC semiconductor devices according to some embodiments of the invention within the mobile electronic devices and mobile systems could provide superior mobile units that could operate much more efficiently and for a much longer time than with prior art technology.

Smart mobile systems may be greatly enhanced by complex electronics at a limited power budget. The 3D technology described in the multiple embodiments of the invention would allow the construction of low power high complexity mobile electronic systems. For example, it would be possible to integrate into a small form function a complex logic circuit with high density high speed memory utilizing some of the 3D DRAM embodiments of the invention and add some non-volatile 3D NAND charge trap or RRAM described in some embodiments of the invention. Mobile system applications of the 3D IC technology described herein may be found at least in FIG. 156 of U.S. Pat. No. 8,273,610, the contents of which are incorporated by reference.

Furthermore, some embodiments of the invention may include alternative techniques to build systems based on integrated 3D devices including techniques and methods to construct 3D IC based systems that communicate with other 3DIC based systems. Some embodiments of the invention may enable system solutions with far less power consumption and intercommunication abilities at lower power than prior art. These systems may be called ‘Internet of Things”, or IoT, systems, wherein the system enabler is a 3DIC device which may provide at least three functions: a sensing capability, a digital and signal processing capability, and communication capability. For example, the sensing capability may include a region or regions, layer or layers within the 3DIC device which may include, for example, a MEMS accelerometer (single or multi-axis), gas sensor, electric or magnetic field sensor, microphone or sound sensing (air pressure changes), image sensor of one or many wavelengths (for example, as disclosed in at least U.S. Pat. Nos. 8,283,215 and 8,163,581, incorporated herein by reference), chemical sensing, gyroscopes, resonant structures, cantilever structures, ultrasonic transducers (capacitive & piezoelectric). Digital and signal processing capability may include a region or regions, layer or layers within the 3D IC device which may include, for example, a microprocessor, digital signal processor, micro-controller, FPGA, and other digital land/or analog logic circuits, devices, and subsystems. Communication capability, such as communication from at least one 3D IC of IoT system to another, or to a host controller/nexus node, may include a region or regions, layer or layers within the 3D IC device which may include, for example, an RF circuit and antenna or antennas for wireless communication which might utilize standard wireless communication protocols such as G4, WiFi or Bluetooth, I/O buffers and either mechanical bond pads/wires and/or optical devices/transistors for optical communication, transmitters, receivers, codecs, DACs, digital or analog filters, modulators.

Energy harvesting, device cooling and other capabilities may also be included in the system. The 3DIC inventions disclosed herein and in the incorporated referenced documents enable the IoT system to closely integrate different crystal devices, for example a layer or layers of devices/transistors formed on and/or within mono or poly crystalline silicon combined with a layer or layers of devices/transistors formed on and/or within Ge, or a layer of layers of GaAs, InP, differing silicon crystal orientations, and so on. For example, incorporating the 3D IC semiconductor devices according to some embodiments of the invention as or within the IoT systems and mobile systems could provide superior IoT or mobile systems that could operate much more efficiently and for a much longer time than with prior art technology. The 3D IC technology herein disclosed provides a most efficient path for heterogeneous integration with very effective integration reducing cost and operating power with the ability to support redundancy for long field life and other advantages which could make such an IoT System commercially successful.

Alignment is a basic step in semiconductor processing. For most cases it is part of the overall process flow that every successive layer is patterned when it is aligned to the layer below it. These alignments could all be done to one common alignment mark, or to some other alignment mark or marks that are embedded in a layer underneath. In today's equipment such alignment would be precise to below a few nanometers and better than 40 nm or better than 20 nm and even better than 10 nm. In general such alignment could be observed by comparing two devices processed using the same mask set. If two layers in one device maintain their relative relationship in both devices—to few nanometers—it is clear indication that these layers are aligned each to the other. This could be achieved by either aligning to the same alignment mark (sometimes called a zero mark alignment scheme), or one layer is using an alignment mark embedded in the other layer (sometimes called a direct alignment), or using different alignment marks of layers that are aligned to each other (sometimes called an indirect alignment).

In this document, the connection made between layers of, generally, single crystal, transistors, which may be variously named for example as thermal contacts and vias, Thru Layer Via (TLV), TSV (Thru Silicon Via), may be made and include electrically and thermally conducting material or may be made and include an electrically non-conducting but thermally conducting material or materials. A device or method may include formation of both of these types of connections, or just one type. By varying the size, number, composition, placement, shape, or depth of these connection structures, the coefficient of thermal expansion exhibited by a layer or layers may be tailored to a desired value. For example, the coefficient of thermal expansion of the second layer of transistors may be tailored to substantially match the coefficient of thermal expansion of the first layer, or base layer of transistors, which may include its (first layer) interconnect layers.

Base wafers or substrates, or acceptor wafers or substrates, or target wafers substrates herein may be substantially comprised of a crystalline material, for example, mono-crystalline silicon or germanium, or may be an engineered substrate/wafer such as, for example, an SOI (Silicon on Insulator) wafer or GeOI (Germanium on Insulator) substrate. Similarly, donor wafers herein may be substantially comprised of a crystalline material and may include, for example, mono-crystalline silicon or germanium, or may be an engineered substrate/wafer such as, for example, an SOI (Silicon on Insulator) wafer or GeOI (Germanium on Insulator) substrate, depending on design and process flow choices.

While mono-crystalline silicon has been mentioned as a transistor material in this document, other options are possible including, for example, poly-crystalline silicon, mono-crystalline germanium, mono-crystalline III-V semiconductors, graphene, and various other semiconductor materials with which devices, such as transistors, may be constructed within. Moreover, thermal contacts and vias may or may not be stacked in a substantially vertical line through multiple stacks, layers, strata of circuits. Thermal contacts and vias may include materials such as sp2 carbon as conducting and sp3 carbon as non-conducting of electrical current. Thermal contacts and vias may include materials such as carbon nano-tubes. Thermal contacts and vias may include materials such as, for example, copper, aluminum, tungsten, titanium, tantalum, cobalt metals and/or silicides of the metals. First silicon layers or transistor channels and second silicon layers or transistor channels may be may be substantially absent of semiconductor dopants to form an undoped silicon region or layer, or doped, such as, for example, with elemental or compound species that form a p+, or p, or p−, or n+, or n, or n− silicon layer or region. A heat removal apparatus may include an external surface from which heat transfer may take place by methods such as air cooling, liquid cooling, or attachment to another heat sink or heat spreader structure. Furthermore, raised source and drain contact structures, such as etch and epi SiGe and SiC, and implanted S/Ds (such as C) may be utilized for strain control of transistor channel to enhance carrier mobility and may provide contact resistance improvements. Damage from the processes may be optically annealed. Strain on a transistor channel to enhance carrier mobility may be accomplished by a stressor layer or layers as well.

In this specification the terms stratum, tier or layer might be used for the same structure and they may refer to transistors or other device structures (such as capacitors, resistors, inductors) that may lie substantially in a plane format and in most cases such stratum, tier or layer may include the interconnection layers used to interconnect the transistors on each. In a 3D device as herein described there may at least two such planes called tier, or stratum or layer.

In a 3D IC system stack, each layer/stratum may include a different operating voltage than other layers/stratum, for example, one stratum may have Vcc of 1.0 v and another may have a Vcc of 0.7 v. For example, one stratum may be designed for logic and have the appropriate Vcc for that process/device node, and another stratum in the stack may be designed for analog devices, and have a different Vcc, likely substantially higher in value-for example, greater than 3 volts, greater than 5 volts, greater than 8 volts, greater than 10 volts. In a 3D IC system stack, each layer/stratum may include a different gate dielectric thickness than other layers/stratum. For example, one stratum may include a gate dielectric thickness of 2 nm and another 10 nm. The definition of dielectric thickness may include both a physical definition of material thickness and an electrically ‘effective’ thickness of the material, given differing permittivity of the materials. In a 3D IC system stack, each layer/stratum may include different gate stack materials than other layers/stratum. For example, one stratum may include a HKMG (High k metal gate) stack and another stratum may include a polycide/silicon oxide gate stack. In a 3D IC system stack, each layer/stratum may include a different junction depth than other layers/stratum. For example, the depth of the junctions may include a FET transistor source or drain, bipolar emitter and contact junctions, vertical device junctions, resistor or capacitor junctions, and so on. For example, one stratum may include junctions of a fully depleted MOSFET, thus its junction depth may be defined by the thickness of the stratum device silicon to the vertical isolation, and the other stratum may also be fully depleted devices with a junction depth defined similarly, but one stratum has a thicker silicon layer than the other with respect to the respective edges of the vertical isolation. In a 3D IC system stack, each layer/stratum may include a different junction composition and/or structure than other layers/stratum. For example, one stratum may include raised source drains that may be constructed from an etch and epitaxial deposition processing, another stratum in the stack may have implanted and annealed junctions or may employ dopant segregation techniques, such as those utilized to form DSS Schottky transistors.

Some 3D device flows presented herein suggest the use of the ELTRAN or modified ELTRAN techniques and in other time a flow is presented using the ion-cut technique. It would be obvious for someone skilled in the art to suggest an alternative process flow by exchanging one layer transfer technique with another. Just as in some steps one could exchange these layer transfer techniques with others presented herein or in other publication such as the bonding of SOI wafer and etch back. These would be variations for the described and illustrated 3D process flows presented herein.

In various places here or in the incorporated by reference disclosures of heat removal techniques have been presented and illustrated. It would be obvious to person skilled in the art to apply these techniques to any of the other variations of 3D devices presented herein.

In various places here or in the incorporated by reference disclosures of repair and redundancy techniques have been presented and illustrated. It would be obvious to person skilled in the art to apply these techniques to any of the other variations of 3D devices presented herein.

In various places here or in the incorporated by reference disclosures memories and other circuit and techniques of customizing and integrating these structures have been presented and illustrated. It would be obvious to person skilled in the art to apply these techniques and structures to any of the other variations of 3D devices presented herein.

It should be noted that one of the design requirements for a monolithic 3D IC design may be that substantially all of the stacked layers and the base or substrate would have their respective dice lines (may be called scribe-lines) aligned. As the base wafer or substrate is processed and multiple circuits may be constructed on semiconductor layers that overlay each other, the overall device may be designed wherein each overlaying layer would have its respective dice lines overlying the dice lines of the layer underneath, thus at the end of processing the entire layer stacked wafer/substrate could be diced in a single dicing step. There may be test structures in the streets between dice lines, which overall may be called scribe-lanes or dice-lanes. These scribe-lanes or dice-lanes may be 10 um wide, 20 um wide, 50 um wide 100 um wide, or greater than 100 um wide depending on design choice and die singulation process capability. The scribe-lanes or dice-lanes may include guard-ring structures and/or other die border structures. In a monolithic 3D design each layer test structure could be connected through each of the overlying layers and then to the top surface to allow access to these ‘buried’ test structure before dicing the wafer. Accordingly the design may include these vertical connections and may offset the layer test structures to enable such connection. In many cases the die borders comprise a protection structure, such as, for example, a guard-ring structure, die seal structure, ESD structure, and others elements. Accordingly in a monolithic 3D device these structures, such as guard rings, would be designed to overlay each other and may be aligned to each other during the course of processing. The die edges may be sealed by a process and structure such as, for example, described in relation to FIG. 183C of incorporated U.S. Pat. No. 8,273,610, and may include aspects as described in relation to FIGS. 183A and 183B of same reference. One skilled in the art would recognize that the die seal can be passive or electrically active. On each 3D stack layer, or stratum, the electronic circuits within one die, that may be circumscribed by a dice-lane, may not be connected to the electronic circuits of a second die on that same wafer, that second die also may be circumscribed by a dice-lane. Further, the dice-lane/scribe-lane of one stratum in the 3D stack may be aligned to the dice-lane/scribe-lane of another stratum in the 3D stack, thus providing a direct die singulation vector for the 3D stack of strata/layers.

An alternative technique is to build an ElectroStatic Discharge (ESD) protection structure very close in proximity to the location of the Input/Output (I/O) pad which connects the device to external circuits. This top most semiconductor layer could include such I/O pads. An ESD structure could be designed to protect against high voltage discharge. It might require a thick semiconductor layer. It might be also desired to keep the uppermost semiconductor layer thin. An alternative to resolve such conflict is to build the ESD structure comprised of polysilicon or amorphous silicon, which might include deposition of polysilicon. Polysilicon and amorphous silicon ESD structure could be constructed according to the teaching in papers by Yang Yang et. al. titled: “Design and Optimization of the SOI Field Effect Diode (FED” and published at IEEE ISDRS 2007 and by Shuqing Cao et. al. titled: “Field Effect Diode for Effective CDM ESD Protection in 45 nm SOI Technology” published by IEEE CFP09RPS-CDR 47th Annual International Reliability Physics Symposium, Montreal, 2009, both of the forgoing incorporated herein by reference.

It will also be appreciated by persons of ordinary skill in the art that the invention is not limited to what has been particularly shown and described hereinabove. For example, drawings or illustrations may not show n or p wells for clarity in illustration. Moreover, transistor channels illustrated or discussed herein may include doped semiconductors, but may instead include undoped semiconductor material. Further, any transferred layer or donor substrate or wafer preparation illustrated or discussed herein may include one or more undoped regions or layers of semiconductor material. Moreover, epitaxial regrow of source and drains may utilize processes such as liquid phase epitaxial regrowth or solid phase epitaxial regrowth, and may utilize flash or laser processes to freeze dopant profiles in place and may also permit non-equilibrium enhanced activation (superactivation). Further, transferred layer or layers may have regions of STI or other transistor elements within it or on it when transferred. Rather, the scope of the invention includes combinations and sub-combinations of the various features described hereinabove as well as modifications and variations which would occur to such skilled persons upon reading the foregoing description.

We claim:

1. A semiconductor device, the device comprising:
a first level of logic circuits, said logic circuits comprise a plurality of first transistors interconnected by a plurality of metal layers;
a thermal isolation layer overlaying said first level;
a second level of memory circuits, said memory circuits comprise an array of memory cells,
wherein said second level is overlaying said thermal isolation layer; and
connections from said logic circuits to said memory array comprising vias,
wherein said vias have a diameter of less than 400 nm, and
wherein a majority of said thermal isolation layer comprises a material with a less than 0.5 W/m·K thermal conductivity.

2. The device according to claim 1,
wherein said device has an unpackaged size less than 0.5 mm for its horizontal or vertical sides.

3. The device according to claim 1,
wherein said thermal isolation layer has a thickness of greater than 200 nm and less than 2 microns.

4. The device according to claim 1,
wherein said second level comprises at least two layers,
wherein one of said at least two layers comprises a first array of memory cells,
wherein another of said at least two layers comprises a second array of memory cells, and
wherein said first array of memory cells overlays at least said second array of memory cells.

5. The device according to claim 1,
wherein said memory cells comprise second transistors, and
wherein said second transistors are aligned to said first transistors with a less than 200 nm misalignment.

6. The device according to claim 1,
wherein said array of memory cells is a random access memory type.

7. The device according to claim 1,
wherein said array of memory cells is a NAND memory type.

8. A semiconductor device, the device comprising:
a first level of logic circuits, said logic circuits comprise a plurality of first transistors interconnected by a plurality of metal layers;
a thermal isolation layer overlaying said first level;
a second level of memory circuits, said memory circuits comprise an array of memory cells,
wherein said second level is overlaying said thermal isolation layer; and
connections from said logic circuits to said memory array comprising vias,
wherein said vias have a diameter of less than 400 nm, and
wherein said thermal isolation layer has a thickness of more than 400 nm and less than 4 microns.

9. The device according to claim 8,
wherein said device has an unpackaged size less than 0.5 mm for its horizontal or vertical sides.

10. The device according to claim 8,
wherein a majority of said thermal isolation layer comprises a material having a less than 0.5 /m·K thermal conductivity.

11. The device according to claim 8,
wherein said second level comprises at least two layers,
wherein one of said at least two layers comprises a first array of memory cells,
wherein another of said at least two layers comprises a second array of memory cells, and
wherein said first array of memory cells overlays at least said second array of memory cells.

12. The device according to claim 8,
wherein said memory cells comprise second transistors, and
wherein said second transistors are aligned to said first transistors with a less than 200 nm misalignment.

13. The device according to claim 8,
wherein said array of memory cells is a random access memory type.

14. The device according to claim 8,
wherein said array of memory cells is a NAND memory type.

15. A semiconductor device, the device comprising:
a first level of logic circuits, said logic circuits comprise a plurality of first transistors interconnected by a plurality of metal layers;
a thermal isolation layer overlaying said first level;
a second level of memory circuits, said memory circuits comprise an array of memory cells,
wherein said second level is overlaying said thermal isolation layer; and
connections from said logic circuits to said memory array comprising vias,
wherein said vias have a diameter of less than 400 nm, and
wherein said device has an unpackaged size less than 0.5 mm for its horizontal or vertical sides.

16. The device according to claim 15,
wherein a majority of said thermal isolation layer comprises a material having a less than 0.5 W/m·K thermal conductivity.

17. The device according to claim 15,
wherein said thermal isolation layer has a thickness greater than 200 nm and less than 2 microns.

18. The device according to claim 15,
wherein said second level comprises at least two layers,
wherein one of said at least two layers comprises a first array of memory cells,
wherein another of said at least two layers comprises a second array of memory cells, and
wherein said first array of memory cells overlays at least said second array of memory cells.

19. The device according to claim 15,
wherein said memory cells comprise second transistors, and
wherein said second transistors are aligned to said first transistors with a less than 200 nm misalignment.

20. The device according to claim 15,
wherein said array of memory cells is a random access memory type.
